(19) United States
(12) Patent Application Publication
(10) Pub. No.: US 2022/0122995 A1
(43) Pub. Date: Apr. 21, 2022

(54) MEMORY CELL AND METHODS THEREOF

(71) Applicant: Ferroelectric Memory GmbH, Dresden (DE)

(72) Inventors: Johannes Ocker, Dresden (DE); Stefan Ferdinand Müller, Dresden (DE)

(21) Appl. No.: 17/072,077

(22) Filed: Oct. 16, 2020

(51) Int. Cl. H01L 27/1159; H01L 49/02; H01L 29/78; H01L 29/51; H01L 29/06; H01L 29/423; H01L 29/786; H01L 29/66

(52) U.S. Cl. CPC H01L 27/1159; H01L 28/60; H01L 29/78391; H01L 29/516; H01L 29/6684; H01L 29/42392; H01L 29/78696; H01L 29/7851; H01L 29/0673

(57) ABSTRACT

According to various aspects, a memory cell is provided, the memory cell including: a capacitive memory structure; and a field-effect transistor structure including a gate isolation, wherein the capacitive memory structure and the field-effect transistor structure are coupled with one another to form a capacitive voltage divider, wherein the gate isolation includes at least one gate isolation layer, the at least one gate isolation layer including a material having a dielectric constant greater than 4, and wherein a thickness of the at least one gate isolation layer is in the range from 3 nm to 10 nm.

### TECHNICAL FIELD

Various aspects relate to a memory cell, an electronic device, and methods thereof, e.g. a method for processing a memory cell and a method for processing an electronic device.

### BACKGROUND

In general, various computer memory technologies have been developed in the semiconductor industry. A fundamental building block of a computer memory may be referred to as memory cell. The memory cell may be an electronic circuit that is configured to store at least one information (e.g., bitwise). As an example, the memory cell may have at least two memory states representing, for example, a logic “1” and a logic “0”. In general, the information may be maintained (stored) in a memory cell until the memory state of the memory cell is modified, e.g., in a controlled manner. The information stored in the memory cell may be obtained by determining in which of the memory states the memory cell is residing in. At present, various types of memory cells may be used to store data. By way of example, a type of memory cell may include a thin film of ferroelectric material, whose polarization state may be changed in a controlled fashion to store data in the memory cell, e.g. in a non-volatile manner. The memory cells may be integrated, for example, on a wafer or a chip together with one or more logic circuits.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. In the following description, various aspects of the invention are described with reference to the following drawings, in which:

FIG. 1 shows schematically a field-effect transistor structure, according to various aspects;

FIG. 2 shows schematically an equivalent circuit diagram of a memory cell, according to various aspects;

FIG. 3A to FIG. 3E each shows schematically a memory cell, according to various aspects;

FIG. 4A to FIG. 4G each shows schematically a field-effect transistor structure, according to various aspects;

FIG. 5 shows a schematic flow diagram of a method for processing a memory cell, according to various aspects; and

FIG. 6A to FIG. 6E show schematically a carrier during processing of an electronic device, according to various aspects.

### DESCRIPTION

The following detailed description refers to the accompanying drawings that show, by way of illustration, specific details and aspects in which the invention may be practiced. These aspects are described in sufficient detail to enable those skilled in the art to practice the invention. Other aspects may be utilized and structural, logical, and electrical changes may be made without departing from the scope of the invention. The various aspects are not necessarily mutually exclusive, as some aspects may be combined with one or more other aspects to form new aspects. Various aspects are described in connection with methods and various aspects are described in connection with devices (e.g., a field-effect transistor structure, a memory cell, or an electronic device). However, it may be understood that aspects described in connection with methods may similarly apply to the devices, and vice versa.

The terms “at least one” and “one or more” may be understood to include any integer number greater than or equal to one, i.e. one, two, three, four, [ . . . ], etc. The term “a plurality” or “a multiplicity” may be understood to include any integer number greater than or equal to two, i.e. two, three, four, five, [ . . . ], etc.

The phrase “at least one of” with regard to a group of elements may be used herein to mean at least one element from the group consisting of the elements. For example, the phrase “at least one of” with regard to a group of elements may be used herein to mean a selection of: one of the listed elements, a plurality of one of the listed elements, a plurality of individual listed elements, or a plurality of a multiple of listed elements.

In the semiconductor industry, the integration of non-volatile memory technologies may be useful for System-on-Chip (SoC) products like microcontrollers (MCU), etc. According to various aspects, a non-volatile memory may be integrated next to a processor core of a processor. As another example, one or more non-volatile memories may be used as part of a mass storage device. In some aspects, a non-volatile memory technology may be based on at least one field-effect transistor (FET) structure. In some aspects, a memory cell may include a field-effect transistor structure and a capacitive memory structure coupled to a gate electrode of the field-effect transistor structure. The amount of charge stored in the capacitive memory structure may influence the threshold voltage(s) of the field-effect transistor structure. The threshold voltage(s) of the field-effect transistor structure may define the memory state the memory cell is residing in. In some aspects, the capacitive memory structure may be a ferroelectric capacitor structure (FeCAP) coupled to a gate electrode of the field-effect transistor structure to provide a ferroelectric field-effect transistor (FeFET) structure. Since a ferroelectric material may have at least two stable polarization states, it may be used to shift a threshold voltage of a field-effect transistor in a non-volatile fashion; therefore, it may be used to turn the field-effect transistor into a non-volatile field-effect transistor based memory structure. A ferroelectric material may turn a ferroelectric capacitor structure into a non-volatile capacitor based memory structure, e.g. by controlling the amount of charge stored in the capacitor structure.

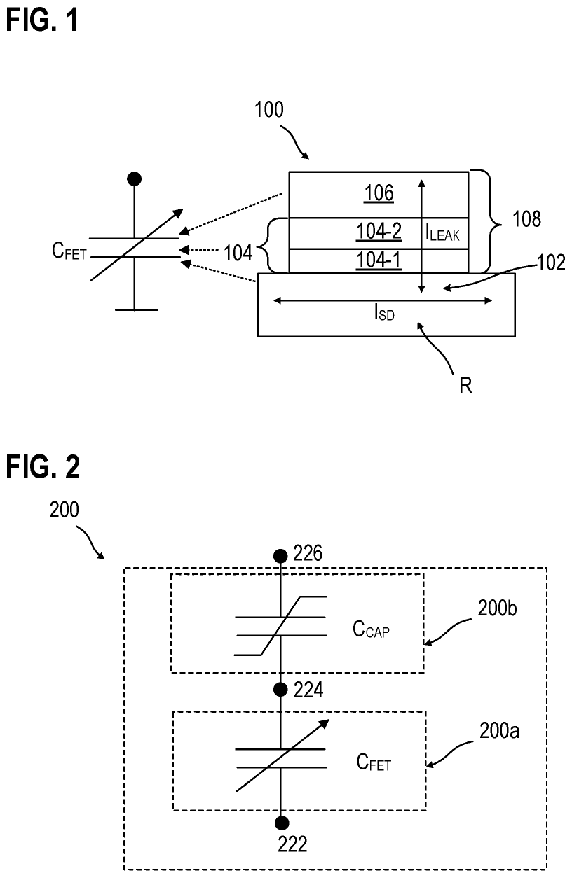

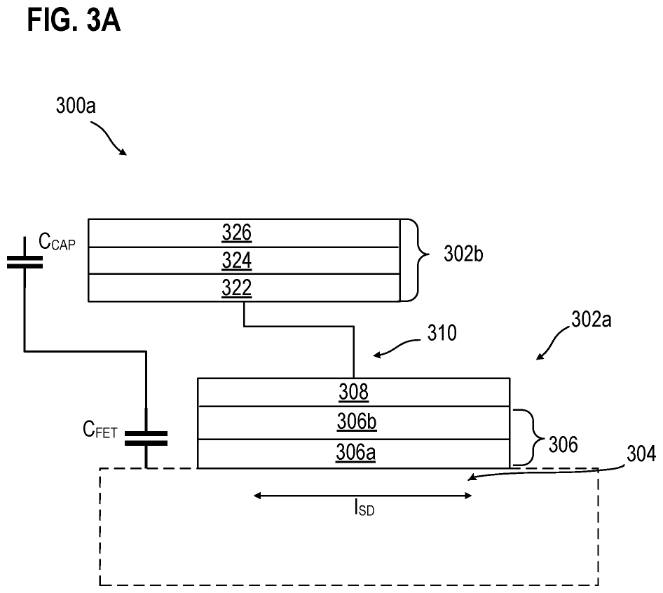

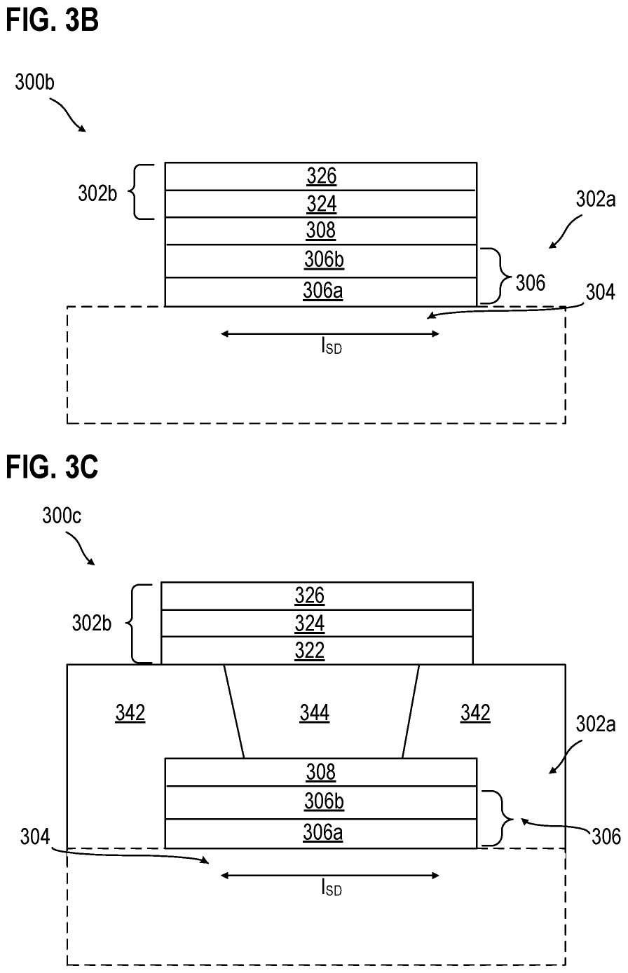

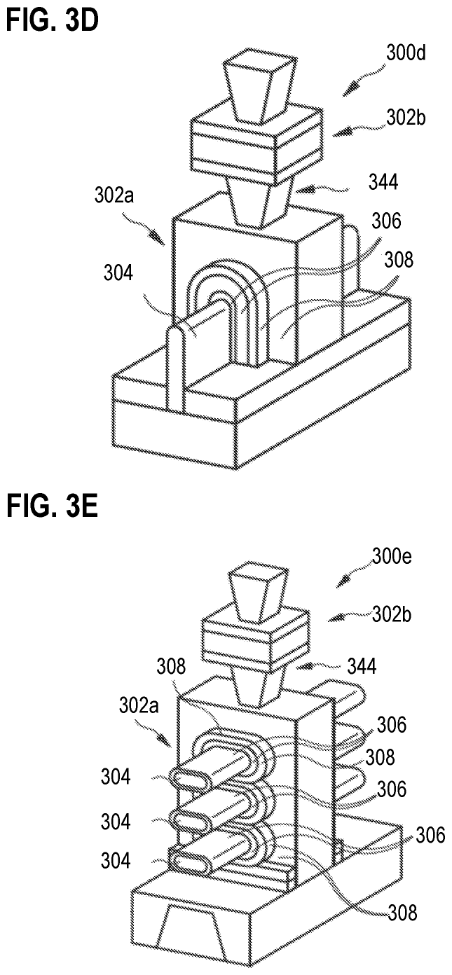

FIG. 1 shows a schematic functioning of a field-effect transistor structure 100, according to various aspects. The field-effect transistor structure 100 may include a gate structure 108, wherein the gate structure 108 may include a gate isolation 104 and a gate electrode 106. The gate structure 108 is illustrated exemplarily as a planar gate stack, however, it may be understood that the planar configuration shown in FIG. 1 is an example, and other field-effect transistor designs may include a gate structure 108 with a non-planar shape, for example a trench gate transistor design, a vertical field-effect transistor design, or other designs as exemplarily shown in FIG. 3D and FIG. 3E, as examples. The gate structure 108 may define a channel region 102, e.g., provided in a semiconductor portion (e.g., in a semiconductor layer, in a semiconductor die, etc.). The gate structure 108 may allow for a control an electrical behavior of the channel region 102. The gate structure 108 may, for example, be used to control (e.g., allow or prevent) a current flow in the channel region 102. In some aspects, the gate structure 108 may, for example, allow to control (e.g., allow or prevent) a source/drain current, I_{SD}, from a first source/drain region of the field-effect transistor structure 100 to a second source/drain region of the field-effect transistor structure 100 (the source/drains are provided in or adjacent to the channel but are not shown in FIG. 1). The channel region 102 and the source/drain regions may be formed, e.g., via doping one or more semiconductor materials or by the use of intrinsically doped semiconductor materials, within a layer and/or over a layer. In some aspects, the gate structure 108 may control (e.g., increase or reduce) an electrical resistance, R, of the channel region 102 and, accordingly, control the amount of current that may flow through the channel region 102. With respect to the operation of the field-effect transistor structure 100, a voltage (illustratively an electrical potential) may be provided at (e.g., supplied to) the gate electrode 106 to control the current flow, I_{SD}, in the channel region 102, the current flow, I_{SD}, in the channel region 102 being caused by voltages supplied via the source/drain regions.

The gate electrode 106 may include an electrically conductive material, for example, polysilicon, aluminum, etc. In some aspects, the gate electrode 106 may include any suitable electrically conductive material, e.g., a metal, a metal alloy, a degenerate semiconductor (in other words a semiconductor material having such a high level of doping that the material acts like a metal and not anymore as a semiconductor). According to various aspects, the gate electrode 106 may include one or more electrically conductive portions, layers, etc. The gate electrode 106 may include, for example, one or more metal layers (also referred to as a metal gate), one or more polysilicon layers (also referred to as poly-Si-gate), etc. A metal gate may include, for example, at least one work-function adaption metal layer disposed over the gate isolation 104 and an additional metal layer disposed over the work-function adaption metal layer. A poly-Si-gate may be, for example, p-type doped or n-type doped.

According to various aspects, the gate isolation 104 may be configured to provide an electrical separation of the gate electrode 106 from the channel region 102 and further to influence the channel region 102 via an electric field generated by the gate electrode 106. The gate isolation 104 may include one or more electrically insulating portions, layers, etc., as described in more detail below.

It is noted that a gate leakage current, I_{LEAK}, may be present (usually inherently) in the field-effect transistor structure 100 resulting in a charge transfer between the gate electrode 106 and the channel region 102, e.g., due to the dimensions of the gate isolation 104, which may cause a tunnel current and/or a leakage current through grain boundaries or other imperfections in the crystallographic structure of the one or more materials forming the gate isolation 104. The leakage current, I_{LEAK}, is usually tolerated for field-effect transistors, i.e. a field-effect transistor may not be specifically designed to have the lowest possible leakage current value since other performance parameters (e.g., switching frequency and/or breakthrough voltages) may be usually in the focus to be optimized for field-effect transistors (e.g., logic transistors and/or I/O transistors) used in electronic devices as, for example, central processing units, system on chips, etc.

Advanced designs of the gate isolation 104 may include at least two layers including different materials, e.g., a first gate isolation layer 104-1 (e.g., a first dielectric layer including a first dielectric material) and a second gate isolation layer 104-2 (e.g., a second dielectric layer including a second dielectric material distinct from first dielectric material). The second gate isolation layer 104-2 may be disposed over the first gate isolation layer 104-1. Illustratively, the first gate isolation layer 104-1 may be disposed closer to the channel region 102 of the field-effect transistor structure 100 with respect to the second gate isolation layer 104-2. The first gate isolation layer 104-1 may be disposed directly on the channel region 102 and may provide an interface for forming the second gate isolation layer 104-2. In some aspects, the first gate isolation layer 104-1 may be referred to as buffer layer.

According to various aspects, the first gate isolation layer 104-1 may include (in some aspects, may be made of) a (first) material having first dielectric constant, e.g. a (relatively) low dielectric constant (also referred to as relative permittivity). In some aspects the material of the first gate isolation layer 104-1 may have a (first) dielectric constant different from (e.g., less than) a (second) dielectric constant of a material of the second gate isolation layer 104-2. In some aspects, the material of the first gate isolation layer 104-1 may have a dielectric constant in the range from 3 to 15, for example a dielectric constant equal to or less than 15, or equal to or less than 4. In some aspects, the first gate isolation layer 104-1 may include (in some aspects, may be made of) low-k dielectric material. The first gate isolation layer 104-1 may be referred to herein, in some aspects, as low-k material layer. A low-k (LK) dielectric material as described herein may include any suitable insulator material that has a dielectric constant less than the dielectric constant of silicon dioxide (SiO₂), e.g. with a relative permittivity εᵣ being equal to or less than 3.9 (in some aspects, equal to or less than 4). In some aspects, the material of the first gate isolation layer 104-1 may include a material having a greater dielectric constant compared to a low-k dielectric material, e.g. a dielectric constant up to 15, for example for providing a suitable substrate for forming (e.g., growing or depositing) a further gate isolation layer with even greater dielectric constant. In some aspects, the material of the first gate isolation layer 104-1 may include silicon dioxide and/or its doped or modified variants (e.g., doped with fluorine or carbon). In some aspects, the material of the first gate isolation layer 104-1 may include at least one of the following: silicon, silicon oxide, silicon nitride, silicon oxynitride, aluminum, aluminum oxide, aluminum nitride, aluminum oxynitride. In some aspects, silicon dioxide may be considered as a low-k material (despite having an “intermediate” dielectric constant), in other words, silicon dioxide in the context of the present application may be understood as a low-k material (e.g., a silicon oxide layer may, in some aspects, be understood as a low-k material layer). It is understood that the materials mentioned herein may represent possible examples, and that any material having the desired properties and applicable in processing of field-effect transistor structures may be used, for example as a material of the first gate isolation layer 104-1.

According to various aspects, the second gate isolation layer 104-2 may include (in some aspects, may be made of) a (second) material having second dielectric constant, e.g. a (relatively) high dielectric constant. In some aspects the material of the second gate isolation layer 104-2 may have a (second) dielectric constant different from (e.g., greater than) the (first) dielectric constant of the material of the first gate isolation layer 104-1. In some aspects, the material of the second gate isolation layer 104-2 may have a dielectric constant greater than 4 (in some aspects greater than 10, greater than 15, or greater than 30, for example 16 or 35). In some aspects, the second gate isolation layer 104-2 may include (in some aspects, may be made of) a high-k dielectric material. The second gate isolation layer 104-2 may be referred to, in some aspects, as high-k material layer. A high-k (HK) dielectric material as described herein may include any suitable insulator material that has a relative permittivity greater than the relative permittivity of silicon dioxide, e.g. with a relative permittivity εᵣ being greater than 3.9 (in some aspects, greater than 4). In some aspects, the material of the second gate isolation layer 104-2 may include, for example, hafnium oxide (HfO₂), zirconium oxide (ZrO₂), lanthanum oxide (La₂O₃), aluminum oxide (Al₂O₃), and their doped/modified variants (e.g. doped with silicon). In some aspects, the material of the second gate isolation layer 104-2 may include at least one of the following: hafnium, zirconium, lanthanum, strontium, calcium, hafnium oxide, zirconium oxide, silicon doped hafnium oxide, lanthanum oxide, strontium titanate, calcium titanate. In some aspects, the material of the second gate isolation layer 104-2 may include at least one of the following: a transition metal oxide (e.g., a doped, alloyed, substituted and/or undoped transition metal oxide), a perovskite (e.g., a doped, alloyed, substituted and/or undoped transition metal perovskite). It is understood that the materials mentioned herein may represent possible examples, and that any material having the desired properties and applicable in processing of field-effect transistor structures may be used, for example as a material of the second gate isolation layer 104-2.

In some aspects, the gate isolation 104 may include gate isolation layers having different chemical composition with respect to one another. In some aspects, the first gate isolation layer 104-1 may have a first chemical composition and the second gate isolation layer 104-2 may have a second chemical composition different from the first chemical composition. By way of example, the second chemical composition may be different from the first chemical composition in at least one of the type of elements or the molar proportions of the elements (e.g., different doping, different content of the participating elements, or the like).

As illustrated by the circuit equivalent in FIG. 1, a first capacitance, C_{FET}, may be associated with the field-effect transistor structure 100. Illustratively, the channel region 102, the gate isolation 104, and the gate electrode 106 may have a capacitance, C_{FET}, associated therewith, originating from the more or less conductive regions (the channel region 102 and the gate electrode 106) separated from one another by the gate isolation 104. Further illustratively, the channel region 102 may be considered as a first capacitor electrode, the gate electrode 106 as a second capacitor electrode, and the gate isolation 104 as a dielectric medium between the two capacitor electrodes. The capacitance, C_{FET}, of the field-effect transistor structure 100 may define one or more operating properties of the field-effect transistor structure 100. The configuration of the field-effect transistor structure 100 (e.g., of the gate isolation 104) may be adapted according to a desired behavior or application of the field-effect transistor structure 100 during operation (e.g., according to a desired capacitance), as described in further detail below.

In general, the capacitance, C, of a planar capacitor structure may be expressed as,

$$C = {ɛ}_{0} {ɛ}_{r} \frac{A}{d} ,$$

with ε₀ being the relative permittivity of the vacuum, A being the effective area of the capacitor, d being the distance of the two capacitor electrodes from one another, and εᵣ being the relative permittivity of the dielectric material disposed between two capacitor electrodes assuming that the whole gap between the two capacitor electrodes is filled with the dielectric material. It is noted that the capacitance of a non-planar capacitor structure or of a modified variant of a planar capacitor structure may be calculated based on equations known in the art.

As an exemplary application, a field-effect transistor structure may be configured for implementing logic operations, e.g. in an electronic device. In this case, the field-effect transistor structure may be referred to as logic transistor or core transistor. A logic transistor may be used, for example, for creating logic gates and for carrying out fast logic operations (e.g., for driving other logic transistors at a clock rate of an electronic device). A logic transistor may be designed for fast operations and/or for driving low capacitances, and to sustain low driving voltages (e.g., around 1 V) provided at the gate electrode. The design of a logic transistor may be focused on realizing the highest possible capacitance (to provide high switching speeds, i.e. to ensure a minimum delay between providing the voltage at the gate electrode and the opening or closing of the channel region) at the expense of the leakage current that may not have the lowest possible value. In other words, a tradeoff may be accepted, in which a moderate leakage current may be tolerated to carry out logic operations at the highest possible speeds. It may not be possible to adapt the design of a logic transistor to have both the highest possible capacitance and the lowest possible leakage current. Illustratively, a higher capacitance may be provided, for example, by a thinner gate isolation, which however also leads to a higher leakage current, whereas a thicker gate isolation may provide a lower leakage current but may not ensure the highest capacitance for achieving the desired switching speed. Furthermore, a logic transistor may always include a silicon oxide-based layer (e.g., a low-k material layer) as the first gate isolation in contact with the semiconductor material of the channel, since, due to processing reasons, silicon oxide may be formed efficiently (e.g., by thermal oxidation) on silicon (e.g., with a high quality interface for implementing logic operations).

As a result, it was found that a logic transistor may work best in the case that the gate isolation consists of a silicon oxide-based layer (e.g., a low-k material layer) and a high-k material layer disposed over the silicon oxide-based layer, wherein the gate isolation has a total thickness less than 5 nm, the silicon oxide-based layer has a thickness in the range from 0.5 nm to 1.5 nm, and the high-k material layer has a thickness in the range from 1 nm to 3 nm.

As another exemplary application, a field-effect transistor structure may be configured for implementing input/output operations, e.g. in an electronic device. In this case, the field-effect transistor structure may be referred to as input/output (I/O) transistor. An I/O transistor may be provided for controlling input and output signals associated with the electronic device. The I/O transistor may be designed for driving large capacitances, and for sustaining large driving voltages (e.g., 3 V) provided at the gate electrode. The design of an I/O transistor may thus be primarily focused on avoiding a voltage breakthrough from the gate electrode to the channel of the transistor, e.g. in ensuring that the transistor has a high breakdown voltage. Therefore, an I/O transistor (compared to logic transistor) may include a relatively thick gate isolation (e.g., with a total thickness of about 10 nm), which may lead to a relatively low capacitance of the I/O transistor structure and, therefore, to a relatively low switching speed.

As a result, it was found that an I/O transistor may work best in the case that the gate isolation consists of a silicon oxide-based layer (e.g., a low-k material layer) and a high-k material layer disposed over the silicon oxide-based layer, wherein the gate isolation has a total thickness of more than 5 nm (e.g., 10 nm), the silicon oxide-based layer has a thickness in the range from 2 nm to 7 nm, and the high-k material layer has a thickness in the range from 1 nm to 3 nm.

According to various embodiments, there may be special applications for a field-effect transistor structure in the field of memory cells. A memory cell may be provided, for example, by coupling a gate of a field-effect transistor structure with a capacitive memory structure, or by integrating a memory structure in the gate structure of a field-effect transistor structure (as shown, for example, in FIG. 2 and FIG. 3A to FIG. 3E). Various embodiments may therefore provide a field-effect transistor structure adapted to memory-cell applications.

Various aspects are based on the finding that the design and the properties of a logic transistor and of an I/O transistor make them not well suited for memory-related applications, e.g. for using them as part of a (capacitor-based) memory cell. It was realized, for example, that memory-related applications may benefit from a field-effect transistor structure having, at the same time, the highest possible capacitance and the lowest possible leakage current. For memory-related applications, the comparatively high capacitance of the field-effect transistor structure may allow coupling a capacitive memory structure to the gate electrode or to integrate a capacitive memory structure into the gate electrode while having a substantial voltage drop (the voltage drop being defined by a ratio of the capacitances) over the capacitive memory structure. This may allow for a reliable switching of a memory state of the capacitive memory cell and for an improvement of data retention capabilities of the memory cell, as described in further detail below. For memory-related applications, the comparatively low leakage current of the field-effect transistor structure may ensure that a memory state may be reliably maintained over a comparatively long time (also referred to as retention). It was found, for example, that the lower the leakage current through the gate isolation of the field-effect transistor structure the higher the retention of the memory cell. Thus, without the finding that also the leakage current in a field-effect transistor structure plays an important role in influencing the capabilities of a memory cell, one may have considered providing a field-effect transistor with a high capacitance for memory-related applications (e.g., a logic transistor), e.g. for providing high switching speed for writing or reading a memory cell, which however would not ensure the improved data retention provided by the adapted field-effect transistor structure described in the following.

According to various aspects, a field-effect transistor structure is described that is specifically adapted for memory-related applications, e.g. a field-effect transistor structure adapted for use in a (capacitor-based) memory cell (e.g., as illustrated in FIG. 2, and in FIG. 3A to FIG. 3E). The field-effect transistor structure being part of a memory cell (e.g., of memory cell 200) is also referred to in the following as a memory field-effect transistor structure, as memory transistor, or as field-effect transistor structure 200a. The memory transistor may have generally the same structure as described herein with reference to the field-effect transistor structure 100. The memory transistor may be based on the identification of a working range in terms of capacitance and leakage current for memory-related applications. The memory transistor may also provide the possibility of down-scaling the (lateral) dimensions of the field-effect transistor, e.g. for its use at a 28 nm technology node, as described in further detail below.

The memory transistor described herein may be provided with a relatively thick gate isolation compared to a logic transistor and may include a relatively thick layer having a material with (relatively) high dielectric constant (e.g., a thick high-k material layer) compared to both the logic transistor and the I/O transistor. The relatively thick gate isolation of the memory transistor may reduce the leakage current in the transistor, and the relatively thick high-k material layer may ensure that a relatively high capacitance may be provided (e.g., a capacitance greater than the capacitance of an I/O transistor and/or less than the capacitance of a logic transistor) despite the comparatively large thickness. The increase in the capacitance provided by the high relative permittivity of the high-k material may balance the reduction in the capacitance provided by the relatively large thickness of the gate isolation.

As a result, it was found that a field-effect transistor for memory applications (a memory transistor) may work best in the case that the gate isolation includes a first gate isolation layer (e.g., a buffer layer) having a minimal thickness or even in case the first gate isolation layer is omitted. The first gate isolation layer of the gate isolation of the memory transistor may have a thickness of less than about 1.5 nm, for example in the range from about 0.25 nm to about 1.5 nm. Illustratively, the first gate isolation layer may be selected relatively thin (e.g., with respect to the second gate isolation layer), since the relative permittivity, εᵣ, of the second gate isolation layer dominates the dielectric properties of the gate-isolation to provide a high capacitance, C_{FET}. In some aspects, the first gate isolation layer may have a multi-layer structure, e.g. may include a plurality of layers including a material with relatively low dielectric constant, for example a plurality of low-k dielectric layers (e.g., including or consisting of the same low-k dielectric material or different low-k dielectric materials). In this case, a total thickness of this multi-layer structure may be less than about 1.5 nm. Furthermore, it was found that a field-effect transistor for memory applications may work best in the case that the gate isolation includes a second gate isolation layer having a thickness greater than 3 nm, e.g., in the range from about 3 nm to about 15 nm, e.g., in the range from about 3 nm to about 10 nm. In some aspects, the thickness of the second gate isolation layer may be at least two times greater than the thickness of the first gate isolation layer, for example at least three times greater or at least five times greater. In some aspects, the second gate isolation layer may have a multi-layer structure, e.g. may include a plurality of layers including a material with relatively high dielectric constant, for example a plurality of high-k dielectric layers (e.g., including or consisting of the same high-k dielectric material or different high-k dielectric materials). In this case a total thickness of this multi-layer structure may be greater than 3 nm, e.g., in the range from about 3 nm to about 15 nm, e.g., in the range from about 3 nm to about 10 nm.

In some aspects, the thickness of the second gate isolation layer of the gate isolation of the memory transistor may be at least two times greater than the thickness of the first gate isolation layer and a sum of the thickness of the first gate isolation layer and the thickness of the second gate isolation layer (e.g., a thickness of the gate isolation) may be at least 8 nm, for example at least 10 nm.

A combination of the material(s) of the first gate isolation layer and of the second gate isolation layer of the gate isolation of the memory transistor is not particularly limited. In some aspects, a dielectric constant of the material of the second gate isolation layer (e.g., a dielectric constant of the high-k dielectric material) may be at least three time greater than a dielectric constant of the material of the first gate isolation layer (e.g., than a dielectric constant of the low-k dielectric material), for example at least five times greater or at least ten times greater. In some aspects, a difference between the dielectric constant of the material of the second gate isolation layer and the dielectric constant of the material of the first gate isolation layer may be at least three, or at least five. In some aspects, the material of the second gate isolation layer may have a relative permittivity, εᵣ, greater than 10, greater than 15, or greater than 30, for example a relative permittivity of 16 or a relative permittivity of 35. In some aspects, the material of the second gate isolation layer may be undoped. In some aspects, the material of the second gate isolation layer may not possess remanent polarization properties (e.g., may not possess ferroelectric properties).

In some aspects, the material of the second gate isolation layer of the gate isolation of the memory transistor may have a crystalline structure. In a logic transistor or in an I/O transistor, described above, a high-k dielectric material having an amorphous structure is preferred for forming (part of) the gate isolation, as the amorphous structure enhances the electrical isolation capabilities of the gate isolation. The formation of grains in a crystal structure may lead to the formation of paths along which a current may leak. In some aspects, the crystalline structure of the material of the second gate isolation layer may provide an increased capacitance (illustratively, a higher dielectric constant, for example in case the high-k material is or includes HfO₂ or ZrO₂). The reduced electrical isolation may be compensated by the relatively large or larger thickness of the second gate isolation layer (e.g., by a high-k dielectric material layer thicker than in a logic transistor or in an I/O transistor).

In some aspects, the crystalline structure of the material of the second gate isolation layer may be of at least one of the following types of crystalline structures: a poly-crystalline structure, a mono-crystalline structure, or an epitaxially formed crystalline structure. In some aspects, the material of the second gate isolation layer may be HfO₂ having a monoclinic structure (with a relative permittivity, εᵣ, of about at least 16). In some aspects, the material of the second gate isolation layer may be ZrO₂ having a tetragonal structure (with a relative permittivity, εᵣ, of about at least 35). It is understood that the crystalline structures (and the materials) mentioned herein serve only as an example, and other structures may be possible, especially dependent on the respective material(s) forming the second gate isolation layer.

The influence of the capacitance of a field-effect transistor structure (e.g., of the memory transistor) on the performance of a memory cell including a capacitive memory structure are described in further detail below.

FIG. 2 shows a circuit equivalent of a memory cell 200 including a field-effect transistor structure 200a (e.g., configured as described here with reference to the memory transistor, e.g., a field-effect transistor structure 100 having a specifically designed gate isolation 104) and a capacitive memory structure 200b, according to various aspects. The field-effect transistor (FET) structure 200a may have a first capacitance, C_{FET}, associated therewith and the capacitive memory structure 200b may have a second capacitance, C_{CAP}, associated therewith.

The field-effect transistor structure 200a and the capacitive memory structure 200b may be coupled (e.g., electrically connected) to one another such that a capacitive voltage divider is provided. The channel or bulk node of the field-effect transistor structure 200a may provide or may be connected to a first node 222, an electrode of the capacitive memory structure 200b may provide or may be connected to a second node 226 and an intermediate conductive portion (electrode, layer, etc.) may provide or may be connected to a floating intermediate node 224. Exemplary realizations of such connected structures will be described in further detail below, for example in relation to FIG. 3A to FIG. 3E.

The capacitive voltage divider formed by the field-effect transistor structure 200a and the capacitive memory structure 200b may allow adapting the capacitances C_{FET}, C_{CAP} of the respective capacitors to allow an efficient programming of the capacitive memory structure 200b. The overall gate voltage required for switching the memory cell 200 from one memory state into another memory state (e.g. from high threshold voltage state to low threshold voltage state, as described below), may become smaller in case the voltage distribution across the field-effect transistor structure 200a and the capacitive memory structure 200b is adapted such that more of the applied gate voltage drops across the functional layer of the capacitive memory structure 200b (e.g., across a remanent-polarizable layer, such as a ferroelectric layer) than across the gate isolation of the field-effect transistor structure 200a. The overall write voltage (illustratively, applied via the nodes 222, 226 to which the field-effect transistor structure 200a and the capacitive memory structure 200b are connected) may thus be reduced by adapting the capacitive voltage divider. The voltage distribution may be determined by voltage divider calculations for a series connection of the capacitors.

That is, in case the capacitance, C_{FET}, of the field-effect transistor structure 200a is increased (e.g., by providing a suitable gate isolation, as described above) a higher fraction of the voltage applied to the series connection drops across the capacitive memory structure 200b. Accordingly, the electric field generated across the gate isolation of the field-effect transistor structure 200a underneath the capacitive memory structure 200b reduces because the voltage drop across this region is reduced.

This leads to a reduced interfacial field stress, which may lead to a reduced wear out of the interface due to, for example, charge injection. Therefore, the reduced electric field generated across the gate isolation may lead to improved endurance characteristics of the memory cell 200, that is, to an increased amount of possible polarization reversals until the memory cell 200 may lose its memory properties.

In some aspects, the functional layer of the capacitive memory structure 200b may be a remanent-polarizable layer. By increasing the capacitance C_{FET} of the field-effect transistor structure 200a (e.g., by providing a gate isolation including a relatively thick layer of material with high dielectric constant), the depolarization field, E_{Dep}, of the remanent-polarizable layer may be reduced. The depolarization field may be expressed by the following set of equations, wherein the indices “FET” refer to the capacitor provided by the field-effect transistor structure 200a and the indices “CAP” refer to the capacitor provided by the capacitive memory structure 200b, as described herein:

$${V}_{F E T} + {V}_{C A P} = 0 , \\ D = {ɛ}_{0} {ɛ}_{F E T} {E}_{F E T} = {ɛ}_{0} {ɛ}_{C A P} {E}_{C A P} + P , \\ {E}_{C A P} ≡ {E}_{D e p} = - {P ( {ɛ}_{0} {ɛ}_{C A P} ( \frac{{C}_{F E T}}{{C}_{C A P}} + 1 ) )}^{- 1} .$$

The depolarization field E_{Dep} may be detrimental to data retention since, depending on its magnitude, it may depolarize the remanent-polarizable layer. However, the magnitude may be reduced by increasing the capacitance ratio C_{FET}/C_{CAP}. Accordingly, in case the capacitance C_{FET} of the field-effect transistor structure 200a is increased, the depolarization field is reduced. This in turn improves the data retention of the memory cell 200.

In a first approximation, the voltage which drops across the memory structure capacitor, V_{CAP}, may be estimated by:

$${V}_{C A P} = {V}_{226} \cdot \frac{{C}_{FET}}{{C}_{F E T} + {C}_{C A P}} ,$$

wherein V₂₂₆ represents the voltage applied to the top node 226 (e.g., to a top electrode of the capacitive memory structure 200b, for example assuming that the node 222 associated with the bulk of the field-effect transistor structure 200a is connected to a base potential, e.g. to ground or 0 V) and the capacitances in general are defined as described above. Suitable parameters for influencing the voltage drop across the capacitive memory structure 200b (e.g., across the ferroelectric capacitor) may be represented by the area ratio between the capacitive memory structure 200b and the field-effect transistor structure 200a, and/or by the relative permittivity of the field-effect transistor structure 200a (e.g., of the gate isolation of the field-effect transistor structure 200a).

In some aspects, an improved performance of the memory cell 200 may be provided in case about 75% of the applied voltage drops across the capacitive memory structure 200b (and about 25% across the field-effect transistor structure 200a). This may be provided, for example, in case the field-effect transistor structure 200a has a capacitor area three times greater than a capacitor area of the capacitive memory structure 200b, as described by the following equation,

$${V}_{C A P} = {V}_{226} \cdot \frac{{C}_{FET}}{{C}_{F E T} + {C}_{C A P}} \overbrace{=}^{3 \cdot {A}_{C A P} = {A}_{F E T}} {V}_{226} \cdot \frac{3}{4} = 0 .75 \cdot {V}_{226} .$$

However, adjusting the voltage distribution by providing a field-effect transistor structure 200a with a large capacitor area may prevent an application of the memory cell 200 at small technology nodes (e.g., at the 28 nm technology node). The adjustment of the voltage distribution in the voltage divider provided by adapting the dielectric constant (and the thickness) of the gate isolation of the field-effect transistor structure 200a (e.g., of a second gate isolation layer thereof), as described above, may allow providing a smaller footprint for the memory cell 200.

In some aspects, the gate isolation of the field-effect transistor structure 200a may be configured such that a ratio of the (first) capacitance C_{FET} of the field-effect transistor structure 200a to the (second) capacitance C_{CAP} of the capacitive memory structure 200b may be in the range from about 1 to about 100, for example in the range from about 1 to about 25, for example in the range from about 2 to about 25, for example in the range from about 1 to about 16, for example the ratio of the first capacitance C_{FET} to the second capacitance C_{CAP} may be 4. In some aspects, the field-effect transistor structure 200a may have substantially the same capacitor area as the capacitive memory structure 200b, so that the ratio of the first capacitance C_{FET} of the field-effect transistor structure 200a to the second capacitance C_{CAP} of the capacitive memory structure 200b may be adapted by adapting the gate isolation, as described above.

In some aspects, the memory cell 200 may have a footprint (defined by consumed area on a substrate (e.g., on a wafer) during integration thereof) that is less than 0.05 μm², for example less than 0.01 μm². In some aspects, a first footprint, F_{GE-FET}, may be associated with the gate electrode of the field-effect transistor structure 200a. The first footprint, F_{GE-FET}, may be less than 0.05 μm², for example less than 0.01 μm². In some aspects, a second footprint, F_{E-GAP}, may be associated with the first/second electrode of the capacitive memory structure 200b. The second footprint, F_{E-CAP}, may be less than 0.05 μm², for example less than 0.01 μm². In some aspects, the first footprint may be less than 8 times (e.g., less than 4 times, e.g., substantially the same as) the second footprint (i.e., F_{GE-FET}<8·F_{E-GAP}).

Increasing the capacitance C_{FET} of the field-effect transistor structure 200a to adjust the gate voltage divider may allow keeping the thickness of the functional layer (e.g., the remanent-polarizable layer) of the capacitive memory structure 200b in an optimal range. By way of example, changing a ferroelectric film thickness may affect the ferroelectric properties of a ferroelectric layer. Therefore, being able to change the gate stack voltage divider without changing the film thickness of a ferroelectric layer as the memory layer may allow implementing a memory cell 200 with optimal performance.

FIG. 3A to FIG. 3E illustrate schematically possible realizations of a respective memory cell 300a, 300b, 300c, 300d, 300e. These memory cells 300a, 300b, 300c, 300d, 300e may be configured such that a field-effect transistor structure 302a and a capacitive memory structure 302b of the respective memory cell 300a, 300b, 300c, 300d, 300e are connected to form a capacitive voltage divider C_{FET}/C_{LAP}, as described with reference to the memory cell 200 in FIG. 2.

Each of the described memory cells 300a, 300b, 300c, 300d, 300e may include a field-effect transistor structure 302a including a channel 304 (also referred to herein as channel region 304), a gate isolation 306, and a gate electrode 308. The channel 304 and the gate electrode 308 may be configured as described above, e.g., with reference to channel 102 and the gate electrode 106 of field-effect transistor structure 100. The gate isolation 306 may be specifically adapted for memory-related applications, e.g., as described above with reference to the memory transistor. The gate isolation 306 may include at least one gate isolation layer, e.g. a first gate isolation layer 306a (e.g., a buffer layer) and a second gate isolation layer 306b, e.g. as described above with reference to the memory transistor.

In some aspects, the first gate isolation layer 306a may be omitted, e.g. in some aspects the gate isolation 306 may extend from the channel region 304 to the gate electrode 308 and may be free of a silicon oxide layer (e.g., may be free of silicon oxide).

In some aspects, the first gate isolation layer 306a may be in direct physical contact with the channel region 304. The second gate isolation layer 306b may be in direct physical contact with the first gate isolation layer 306a and with the gate electrode 308 of the field-effect transistor structure 302a.

Each of the described memory cells 300a, 300b, 300c, 300d, 300e may include a capacitive memory structure 302b electrically connected (in other words, electrically coupled) with the field-effect transistor structure 302a. The capacitive memory structure 302b may include any type of planar or non-planar design with at least a first electrode 322, a second electrode 326 and at least one remanent-polarizable layer 324 disposed between the first electrode 322 and the second electrode 326, e.g. to provide memory functions.

As described above with reference to the memory cell 200 in FIG. 2, the field-effect transistor structure 302a and the capacitive memory structure 302b may be connected to form a capacitive voltage divider C_{FET}/C_{CAP}, e.g., by connecting one of the electrodes of the capacitive memory structure 302b (e.g., the first electrode 322) with the gate electrode 308 of the field-effect transistor structure 302a, as shown for example in FIG. 3A. The electrically conductive connection of the capacitive memory structure 302b with the field-effect transistor structure 302a (e.g., of the first electrode 322 with the gate electrode 308) may provide a series capacitive connection between the capacitors formed by the capacitive memory structure 302b and the field-effect transistor structure 302a. In a planar configuration, the first electrode 322 of the capacitive memory structure 302b may be a first capacitor electrode, the second electrode 326 may be a second capacitor electrode, and the at least one remanent-polarizable layer 324 may be a dielectric medium between the first electrode and the second capacitor electrode.

In some aspects, the gate electrode 308 of the field-effect transistor structure 302a may be electrically conductively connected to the first electrode 322 of the capacitive memory structure 302b via an electrically conductive (e.g., ohmic) connection 310, as shown in FIG. 3A. In some aspects, the first electrode 322 of the capacitive memory structure 302b may be in direct physical contact with the gate electrode 308 of the field-effect transistor structure 302a.

In some aspects, the capacitive memory structure 302b and the field-effect transistor structure 302a may share a common electrode acting as gate electrode of the field-effect transistor structure 302a and as electrode of the capacitive memory structure 302b, as shown in FIG. 3B.

In some aspects, the electrically conductive (e.g., ohmic) connection 310 between the field-effect transistor structure 302a and the capacitive memory structure 302b may be provided by one or more metallization structures disposed over the field-effect transistor structure 302a, as shown in FIG. 3C.

The at least one remanent-polarizable layer 324 may include any type of remanent-polarizable and/or spontaneously-polarizable material, e.g., a ferroelectric material, an anti-ferroelectric material, an anti-ferroelectric-like material, etc. The at least one remanent-polarizable layer 324 may be the functional layer of the capacitive memory structure 302b to store, for example, an information via at least two remanent polarization states of the at least one remanent-polarizable layer 324. The programming of the capacitive memory structure 302b (illustratively the storage of information therein) may be carried out by providing an electric field between the first electrode 322 and the second electrode 326 (e.g., an electric potential difference between a first node and a second node associated with the first electrode 322 and the second electrode 326, respectively, as described in relation to FIG. 2) to thereby set or change the remanent polarization state of the at least one remanent-polarizable layer 324. As an example, a voltage may be provided between the top electrode 326 and the bulk region of the field-effect transistor structure 302a.

It is understood that a remanent-polarizable layer 324 is only an example of a possible functional layer of the capacitive memory structure 302b, and any other functional layer whose state may be altered by an electric field provided across the capacitive memory structure 302b may be used. In some aspects, a material of the remanent-polarizable layer 324 may include hafnium and/or zirconium.

In general, a remanent polarization (also referred to as retentivity or remanence) may be present in a material layer in the case that the material layer may remain polarized upon reduction of an applied electric field (E) to zero, therefore, a certain value for the electrical polarization (P) of the material layer may be detected. Illustratively, a polarization remaining in a material when the electric field is reduced to zero may be referred to as remanent polarization. Therefore, the remanence of a material may be a measure of the residual polarization in the material in the case that an applied electric field is removed. In general, ferroelectricity and anti-ferroelectricity may be concepts to describe a remanent polarization of a material similar to ferromagnetism and anti-ferromagnetism used to describe remanent magnetization in magnetic materials.

According to various aspects, a ferroelectric material may be used as part of a capacitive memory structure of a memory cell (e.g., as part of the capacitive memory structure 302b of a memory cell 300a, 300b, 300c, 300d, 300e, or of the capacitive memory structure 200b of the memory cell 200). A ferroelectric material may be an example of material of a remanent-polarizable layer (e.g., of the remanent-polarizable layer 324). Illustratively, ferroelectric materials may be used to store data in non-volatile manner in integrated circuits. The term “ferroelectric” may be used herein, for example, to describe a material that shows a hysteretic charge voltage relationship (Q-V). The ferroelectric material may be or may include at least one of the following: hafnium oxide (ferroelectric hafnium oxide, HfO₂), zirconium oxide (ferroelectric zirconium oxide, ZrO₂), a (ferroelectric) mixture of hafnium oxide and zirconium oxide. Ferroelectric hafnium oxide may include any form of hafnium oxide that may exhibit ferroelectric properties. Ferroelectric zirconium oxide may include any form of zirconium oxide that may exhibit ferroelectric properties. This may include, for example, hafnium oxide, zirconium oxide, a solid solution of hafnium oxide and zirconium oxide (e.g. but not limited to it a 1:1 mixture) or hafnium oxide and/or zirconium oxide doped or substituted with one or more of the following elements (non-exhaustive list): silicon, aluminum, gadolinium, yttrium, lanthanum, strontium, zirconium, any of the rare earth elements or any other dopant (also referred to as doping agent) that is suitable to provide or maintain ferroelectricity in hafnium oxide or zirconium oxide. The ferroelectric material may be doped at a concentration from about 2 mol % to about 6 mol %, only as an example.

According to various aspects, a memory cell (e.g., a memory cell 200, 300a, 300b, 300c, 300d, 300e), may have at least two distinct states associated therewith, for example with two distinct electrical conductivities or two distinct amounts of stored charge that may be determined to determine in which of the at least two distinct states the memory cell is residing in. According to various aspects, a memory state the memory cell is residing may be a “programmed state” or an “erased state”. As an example, the programmed state may be an electrically conducting state or a state with positive stored charge (e.g. associated with a logic “1”) and the erased state may be an electrically non-conducting state or a state with negative stored charge (e.g., associated with a logic “0”). However, the definition of programmed state and erased state may be selected arbitrarily.

According to various aspects, the residual polarization of the remanent-polarizable layer may define the memory state a memory cell is residing in. The polarization state of the remanent-polarizable layer may be switched by means of the capacitive memory structure. The polarization state of the remanent-polarizable layer may also be read out by means of the capacitive memory structure. According to various aspects, a memory cell may reside in a first memory state in the case that the remanent-polarizable layer is in a first polarization state, and the memory cell may reside in a second memory state in the case that the remanent-polarizable layer is in a second polarization state (e.g., opposite to the first polarization state). As an example, the polarization state of the remanent-polarizable layer may determine the amount of charge stored in the capacitive memory structure. The amount of charge stored in the capacitive memory structure may be used to define a memory state of the memory cell. The threshold voltage of a field-effect transistor structure (e.g., the field-effect transistor structure 200a, the field-effect transistor structure 302a) may be a function of the amount and/or polarity of charge stored in the capacitive memory structure, e.g. on the polarization state of the remanent-polarizable layer. A first threshold voltage, e.g. a high threshold voltage V_{H-th}, may be associated with the first polarization state (e.g., with the first amount and/or polarity of stored charge), and a second threshold voltage, e.g. a low threshold voltage V_{L-th}, may be associated with the second polarization state (e.g., with the second amount and/or polarity of stored charge). Illustratively, the first memory state may be associated with the first threshold voltage, and the second memory state may be associated with the second threshold voltage.

According to various aspects, the second gate isolation layer 306b of the gate isolation 306 of the field-effect transistor structure 302a may be a layer different from a functional layer of the capacitive memory structure 302b (e.g., different from the remanent-polarizable layer 324), e.g. different in at least one of the type of material(s) or the remanent-polarizable properties of the material(s). By way of example, the material of the second gate isolation layer 306b may not possess remanent-polarizable properties, e.g. it may not possess ferroelectric properties.

According to various aspects, the semiconductor portion (illustratively, where the channel region 304 may be formed), may be made of or may include silicon. However, other semiconductor materials of various types may be used in a similar way, e.g. germanium, Group III to V (e.g. SiC), or other types, including for example carbon nanotubes, organic materials (e.g., organic polymers), etc. In various aspects, the semiconductor portion may be a wafer made of silicon (e.g. p-type doped or n-type doped). In other aspects, the semiconductor portion may be a silicon on insulator (SOI) wafer. In other aspects, the semiconductor portion may be provided by a semiconductor structure, e.g., by one or more semiconductor fins, one or more semiconductor nanosheets, one or more semiconductor nanowires, etc., disposed at a carrier.

FIG. 3C shows an exemplary integration scheme for a memory cell 300c in a schematic view, according to various aspects, in which a metallization structure is provided to electrically connect the field-effect transistor structure 302a to the capacitive memory structure 302b. It is understood that the metallization structure may include a plurality of metallization structures, e.g. a plurality of single- or multi-level contact structures.

The metallization structure may be configured to electrically conductively connect the gate electrode 308 of the field-effect transistor structure 302a and the first electrode 322 of the capacitive memory structure 302b with one another. As an example, the metallization structure may include a contact metallization. The contact metallization may be at least partially disposed between the field-effect transistor structure 302a and the capacitive memory structure 302b. As another example, the metallization structure may include a contact metallization and a single- or multi-level metallization disposed over the contact metallization. In this case, both the contact metallization and at least one level of the single- or multi-level metallization may be disposed between the field-effect transistor structure 302a and the capacitive memory structure 302b.

In some aspects, the metallization structure may be disposed over an active area of the field-effect transistor structure 302a, and the capacitive memory structure 302b may be disposed over the metallization structure (i.e. over the active area of the field-effect transistor structure 302a). This configuration may herein be referred to as capacitor over active area (COAA) structure. The COAA structure may allow providing a memory cell with reduced overall (lateral) dimensions, e.g. for facilitating its application at the 28 nm technology node. By arranging the capacitive memory structure 302b (e.g., as ferroelectric capacitor) above the field-effect transistor structure 302a the full scaling potential (e.g., the desired footprint) may be maintained.

The metallization structure may include a gate contact structure 344 (also referred to as gate contact). The gate contact structure 344 may be embedded in (e.g., may be laterally surrounded by) an insulator layer 342. The insulator layer 342 may include a dielectric material, e.g., silicon oxide (SiO₂), silicon nitride (SiNₓ), etc., having, for example, a thickness in the range from about 10 nm to about 100 nm, e.g., a thickness of 40 nm. In some aspects, the insulator layer 342 may include a plurality of insulator layers, e.g. each including a same material or different materials. The gate contact structure 344 may include at least one metal layer, e.g., including tungsten (W), cobalt (Co), etc. The gate contact structure 344 may be in direct physical contact with the gate electrode 308 of the field-effect transistor structure 302a. The gate contact structure 344 may be in direct physical contact with the first electrode 322 of the capacitive memory structure 302b. According to various aspects, the electrical connection between the first electrode 322 of the capacitive memory structure 302b and the gate electrode 308 of the field-effect transistor structure 302a may be formed by the gate contact structure 344.

A further metallization structure (shown, for example, in FIG. 3D and FIG. 3E) may be formed over the capacitive memory structure 302b. The further metallization structure may include a memory contact structure (also referred to as memory contact). The memory contact structure may be embedded in (e.g., may be laterally surrounded by) a further (e.g., second) insulator layer.

FIG. 3D and FIG. 3E illustrate possible non-planar structures for a memory cell 300d, 300e, e.g. for a field-effect transistor structure 302a (e.g., for a memory transistor described above).

In the integration scheme shown in FIG. 3D, at least the field-effect transistor structure 302a of the memory cell 300d may be configured as a fin field-effect transistor (FinFET). The semiconductor portion in which the channel region 304 is provided may have the shape of a vertical fin, wherein the gate isolation 306 and the gate electrode 308 may at least partially surround the fin.

In the integration scheme shown in FIG. 3E, at least the field-effect transistor structure 302a of the memory cell 300e may be configured as a nanosheet or nanowire field-effect transistor. The one or more semiconductor portions, in which a channel region 304 is provided, may each have the shape of a nanosheet or nanowire. The gate isolation 306 and the gate electrode 308 may at least partially surround the respective nanosheets or nanowires.

For ferroelectric HfO₂, its ferroelectric properties may likely disappear when the layer thickness is reduced to below 2 nm or at least when the reduction in film thickness leads to an unacceptable increase of the crystallization temperature such that the ferroelectric phase in HfO₂ cannot be stabilized anymore. Therefore, according to various aspects, a layer thickness for a ferroelectric HfO₂ layer used in a capacitive memory structure may be selected greater than or equal to 2 nm. For the most advanced transistor platforms, e.g., illustrated exemplarily in FIG. 3D and FIG. 3E, it may be beneficial to arrange the ferroelectric HfO₂ layer above the field-effect transistor structure, so that the ferroelectric HfO₂ layer can be implemented with the desired layer thickness in these process platforms.

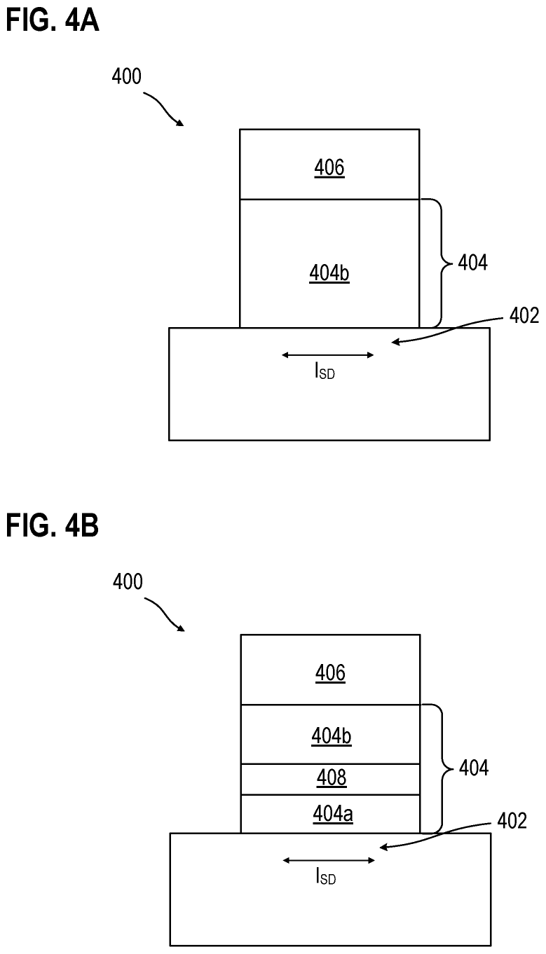

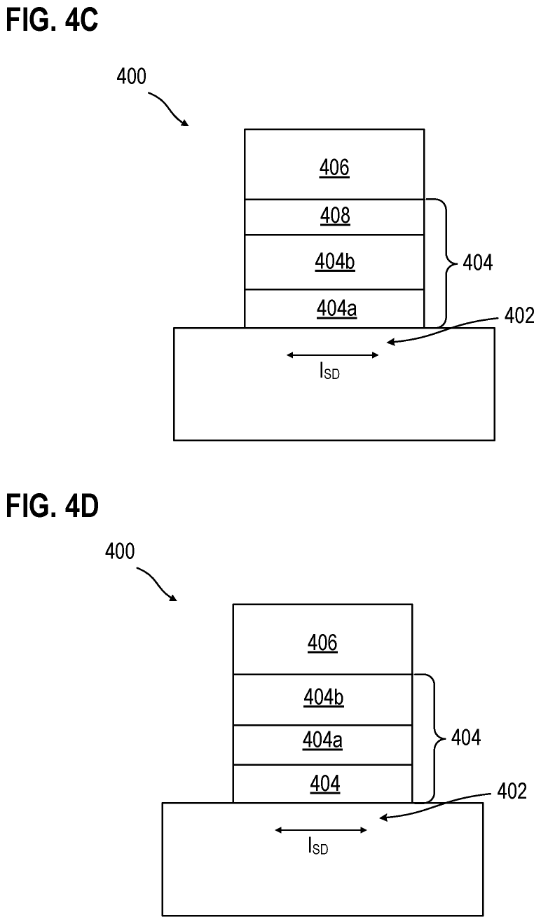

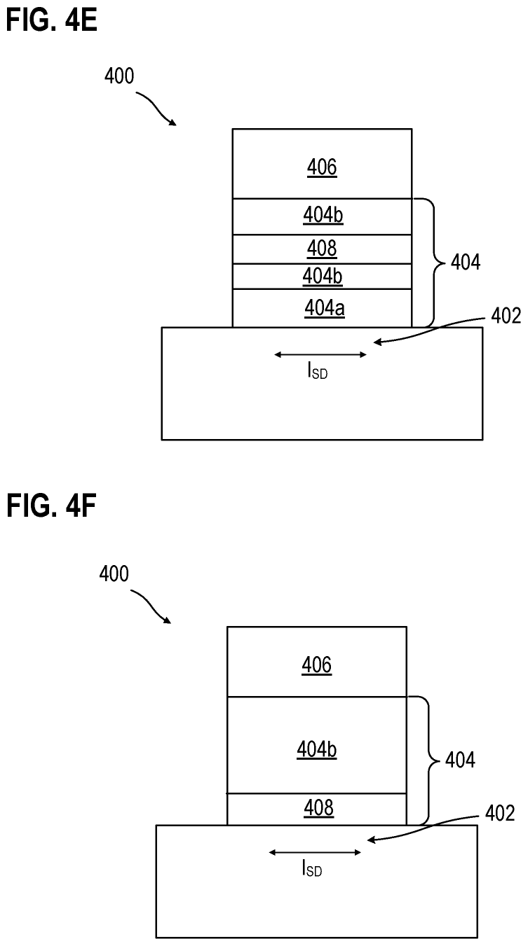

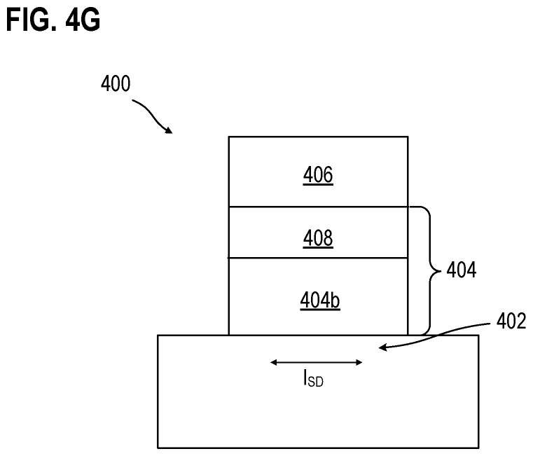

FIG. 4A to FIG. 4G illustrate a field-effect transistor structure 400 in a schematic view, in accordance with various aspects.

The field-effect transistor structure 400 may be a field-effect transistor structure adapted for memory-related applications, e.g. may be an example of a memory transistor as described above. In some aspects, the field-effect transistor structure 400 may be an exemplary implementation of the field-effect transistor structure 302a described in FIG. 3A to FIG. 3E.

The field-effect transistor structure 400 may include a channel 402 (also referred to herein as channel region 402), a gate isolation 404, and a gate electrode 406. The channel 402 and the gate electrode 406 may be configured as described above, e.g., with reference to the channel 102 and the gate electrode 106 of the field effect transistor structure 100 (and/or with reference to the channel 304 and the gate electrode 308 of the field effect transistor structure 302a). The gate isolation 404 may be specifically adapted for memory related applications, e.g., as described above with reference to the memory transistor. The gate isolation 404 may include a first gate isolation layer 404a (e.g., a buffer layer) and a second gate isolation layer 404b, e.g. as described above with reference to the memory transistor (e.g., as described above with reference to the first gate isolation layer 306a and the second gate isolation layer 306b). In some aspects, the first gate isolation layer 404a may be omitted (see FIG. 4A, FIG. 4F, and FIG. 4G).

The gate structure of the field-effect transistor structure 400 is illustrated exemplarily as a planar gate stack, however, it may be understood that the planar configuration shown in FIG. 4A to FIG. 4G is an example, and other field-effect transistor designs may include a gate structure with a non-planar shape, for example a trench gate transistor design, a vertical field effect transistor design, or other designs as described above.

In some aspects, as illustrated for example in FIG. 4A, the first gate isolation layer 404a may be dispensed with. Illustratively, in some aspects, the gate isolation 404 may consist of a material having a relatively high dielectric constant, e.g. of a material having a dielectric constant greater than 4 (e.g., of a high-k dielectric material). In some aspects, the gate isolation 404 may consist of a material having a dielectric constant greater than 15. The second gate isolation layer 404b may be in direct physical contact with the channel region 402 and with the gate electrode 406 of the field-effect transistor structure 400, e.g. the second gate isolation layer 404b may extend from the channel region 402 to the gate electrode 406 of the field-effect transistor structure 400. Illustratively, in some aspects the gate isolation 404 may include the second gate isolation layer 404b as the (only) at least one gate isolation layer, e.g. the gate isolation may be free of a silicon oxide layer. An interface may be formed between the second gate isolation layer 404b and the channel region 402 (e.g., between the second gate isolation layer 404b and the semiconductor portion). This configuration may provide a higher capacitance with respect to a gate isolation 404 including also a first gate isolation layer 404a.

In some aspects, as illustrated for example in FIG. 4B to FIG. 4G, the gate isolation 404 may include an additional electrically isolating layer 408. The additional electrically isolating layer 408 may further contribute to reducing the leakage current in a field-effect transistor structure, e.g. in a memory transistor. In some aspects, the additional electrically isolating layer 408 may include an electrically insulating material, for example a dielectric material such as an oxide material (e.g., Al₂O₃ or SiO₂) or a nitride material. In some aspects, the additional electrically isolating layer 408 may have a thickness in the range from about 0.5 nm to about 1.5 nm, for example from about 1 nm to about 3 nm.

The additional electrically isolating layer 408 may be disposed in various positions within the gate isolation 404, as described in further detail below in relation to FIG. 4B to FIG. 4G. In the figures a single additional electrically isolating layer 408 is shown. It is however understood that the gate isolation 404 may include a plurality of additional electrically isolating layers 408 (e.g., including the same electrically insulating material or different electrically insulating materials), for example disposed in different positions within the gate isolation 404.

As shown in FIG. 4B, the additional electrically isolating layer 408 may be disposed between the first gate isolation layer 404a and the second gate isolation layer 404b, e.g. the additional electrically isolating layer 408 may be in direct physical contact with both the first gate isolation layer 404a and the second gate isolation layer 404b.

As shown in FIG. 4C, the additional electrically isolating layer 408 may be disposed over the second gate isolation layer 404b, e.g. between the second gate isolation layer 404b and the gate electrode 406. Illustratively, the additional electrically isolating layer 408 may be in direct physical contact with the second gate isolation layer 404b and the gate electrode 406.

As shown in FIG. 4D, the additional electrically isolating layer 408 may be disposed below the first gate isolation layer 404a, e.g. between the first gate isolation layer 404a and the channel region 402. Illustratively, the additional electrically isolating layer 408 may be in direct physical contact with the first gate isolation layer 404a and the channel region 402.

As shown in FIG. 4E, the additional electrically isolating layer 408 may be disposed within the second gate isolation layer 404b, e.g. between a first portion of the second gate isolation layer 404b and a second portion of the second gate isolation layer 404b. Similarly (not shown), the additional electrically isolating layer 408 may be disposed within the first gate isolation layer 404a, e.g. between a first portion of the first gate isolation layer 404a and a second portion of the first gate isolation layer 404a.

As shown in FIG. 4F and FIG. 4G, the additional electrically isolating layer 408 may be provided also in case the gate isolation 404 does not include the first gate isolation layer 404a. In this case, the additional electrically isolating layer 408 may be disposed over the second gate isolation layer 404b, e.g. between the second gate isolation layer 404b and the gate electrode 406 (see FIG. 4F), and/or below the second gate isolation layer 404b, e.g. between the second gate isolation layer 404b and the channel region (see FIG. 4G), and/or within the second gate isolation layer 404b (not shown).

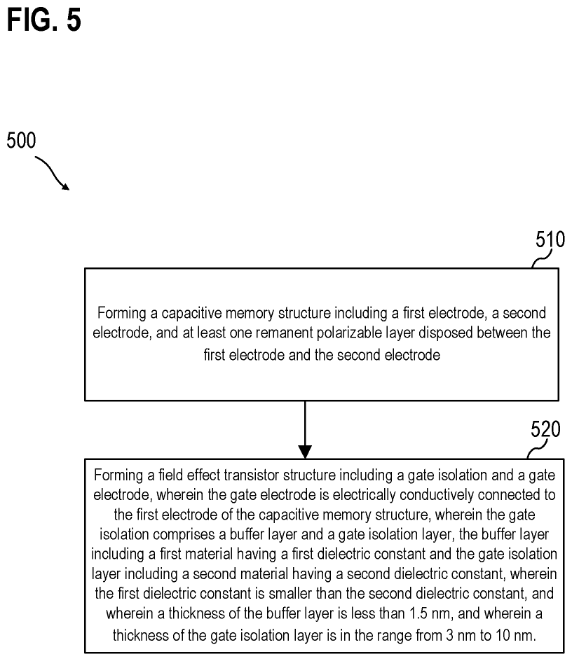

FIG. 5 illustrates a schematic flow diagram of a method 500 for processing a memory cell, e.g. for processing the memory cell 200 described in relation to FIG. 2 and/or the memory cell 300a, 300b, 300c, 300d, 300e described in relation to FIG. 3A to FIG. 3E, according to various aspects.

The method 500 may include: in 510, forming a capacitive memory structure; and in 520 forming a field-effect transistor structure including a gate isolation and a gate electrode wherein the capacitive memory structure and the field-effect transistor structure are coupled with one another to form a capacitive voltage divider. The gate isolation may include a buffer layer (e.g., a first gate isolation layer) and a (e.g., second) gate isolation layer, the buffer layer including a first material having a first dielectric constant and the gate isolation layer including a second material having a second dielectric constant. The first dielectric constant may be less than the second dielectric constant (for example, a difference between the second dielectric constant and the first dielectric constant may be at least three, or at least five). The buffer layer may have a thickness of less than about 1.5 nm, for example in the range from about 0.25 nm to about 1.5 nm. The gate isolation layer may have a thickness greater than 3 nm, e.g., in the range from about 3 nm to about 15 nm, e.g., in the range from about 3 nm to about 10 nm.

In some aspects, the first dielectric constant may be in the range from 3 to 15, for example the first dielectric constant may be equal to or less than 15, or less than or equal to 4. The second dielectric constant may be greater than 4, in some aspects greater than 15. In some aspects, the buffer layer may be a low-k dielectric layer, and the gate isolation layer may be a high-k dielectric layer.

In some aspects, the capacitive memory structure may include a first electrode, a second electrode, and at least one remanent-polarizable layer disposed between the first electrode and the second electrode. In some aspects, an electrode (e.g., the first electrode) of the capacitive memory structure may be electrically conductively connected with the gate electrode of the field-effect transistor structure.

In some aspects, the thickness of the gate isolation layer may be at least two times greater than the thickness of the buffer layer, for example at least three times greater or at least five times greater.

In some aspects, the thickness of the gate isolation layer may be at least two times greater than the thickness of the buffer layer and a sum of the thickness of the buffer layer and the thickness of the gate isolation layer (e.g., a thickness of the gate isolation) may be at least 8 nm, for example at least 10 nm.

In some aspects, the buffer layer may be dispensed with, e.g. the gate isolation may consist of the gate isolation layer (e.g., of a material having the second dielectric constant), e.g. having a thickness in the range from about 3 nm to about 10 nm, for example from about 5 nm to about 15 nm, for example from about 8 nm to about 20 nm. Illustratively, in some aspects, the gate isolation may consist of a high-k material layer.

In some aspects, the method 500 may include one or more layering and patterning processes for processing the memory cell, e.g. for forming the memory structure and/or the field-effect transistor structure.

The layering may include forming (optionally) a buffer layer, a gate isolation layer, and a gate electrode. The patterning may include forming a mask (e.g., a silicon nitride hard mask having a thickness in the range from about 5 nm to about 100 nm) defining the lateral dimension of the field-effect transistor structure, e.g. of a gate structure thereof, and partially removing the buffer layer, the gate isolation layer, and the gate electrode.

Forming the field-effect transistor structure may include forming doped regions in a carrier, e.g. in a semiconductor substrate or portion, e.g. to form at least two source/drain regions of the field-effect transistor structure. Various doping techniques may be used to form the at least two source/drain regions, e.g. diffusion doping, ion implantation, or the like. Forming the field-effect transistor structure may include layering and patterning a gate structure at a (channel) region between the doped regions forming the at least two source/drain regions.

The layering may include forming a first electrode layer (e.g., a bottom electrode layer), a second electrode layer (e.g., a top electrode layer), and at least one remanent-polarizable layer disposed between the two electrode layers. The patterning may include forming a mask (e.g., a silicon nitride hard mask having a thickness in the range from about 5 nm to about 100 nm) defining the lateral dimension of the capacitive memory structure and partially removing the electrode layers and the at least one remanent-polarizable layer to form the capacitive memory structure. The capacitive memory structure may be formed over a metallization structure (illustratively the contact metallization) including a gate contact structure.

According to various aspects, the gate contact structure may be formed by depositing an insulator material (for example SiO₂ or SiN) across the whole carrier and by forming a contact hole above the gate structure for each field-effect transistor structure of the memory cell (e.g., by one or more lithography processes and wet or dry chemical etching). The contact hole may be either directly formed above the gate structure, i.e. above the active area, or, if this is not possible (e.g. because of design rules), then the contacting of the gate structure may be done with an offset to the active area.

According to various aspects, one or more field-effect transistor structures may be formed in a HK-first or HK-last process flow. A HK-last process flow may include forming a dummy gate structure having a dummy gate isolation and a dummy gate electrode. Further, after the dummy gate isolation and the dummy gate electrode are removed, the actual high-k material for the gate isolation and one or more materials (e.g., one or more metals) for the gate electrode may be deposited.

According to various aspects, one or more field-effect transistor structures may be formed in a metal-last process flow. A metal-last process flow may include forming a dummy gate structure having a gate isolation and a dummy gate electrode. Further, after the dummy gate electrode is removed, the one or more materials (e.g., one or more metals) for the actual gate electrode may be deposited. In contrast to a HK-last process flow, the gate isolation (e.g., the high-k material) may remain (may not be substantially removed).

According to various aspects, one or more patterning processes may be used to form a field-effect transistor structure and/or a capacitive memory structure, e.g., at least one of over or in a carrier. Therefore, a mask may be used. A mask may include a material that serves for transferring a photo-lithography mask pattern into one or more material layers. A mask may include, for example, a positive or negative photo resist (also referred to as soft mask) or a hard mask. The photo resist itself may be patterned by standard lithography processes. The patterning of the hard mask material may include a combination of photo resist patterning followed by etch of the hard mask material (e.g. wet or dry chemical etching). However, any other suitable process may be used to transfer a desired pattern into one or more material layers.

According to various aspects, a memory cell as described herein may be integrated in an electronic device (e.g., e.g., a microcontroller, a central processing unit, a system on a chip (SoC), a memory device), for example in a same electronic device with other components, such as components to control logic operations and/or input/output operations of the electronic device. Illustratively, one or more memory transistors may be integrated (and formed) on or in a same carrier as one or more logic transistors and/or one or more input/output transistors.

The processing (e.g., the fabrication) of a memory transistor may be integrated in a process flow for processing an electronic device. Illustratively, the processing of a memory transistor may be carried out in parallel with the processing of logic transistors and/or I/O transistors used in an electronic device, e.g. to provide an electronic device with data storage capabilities.

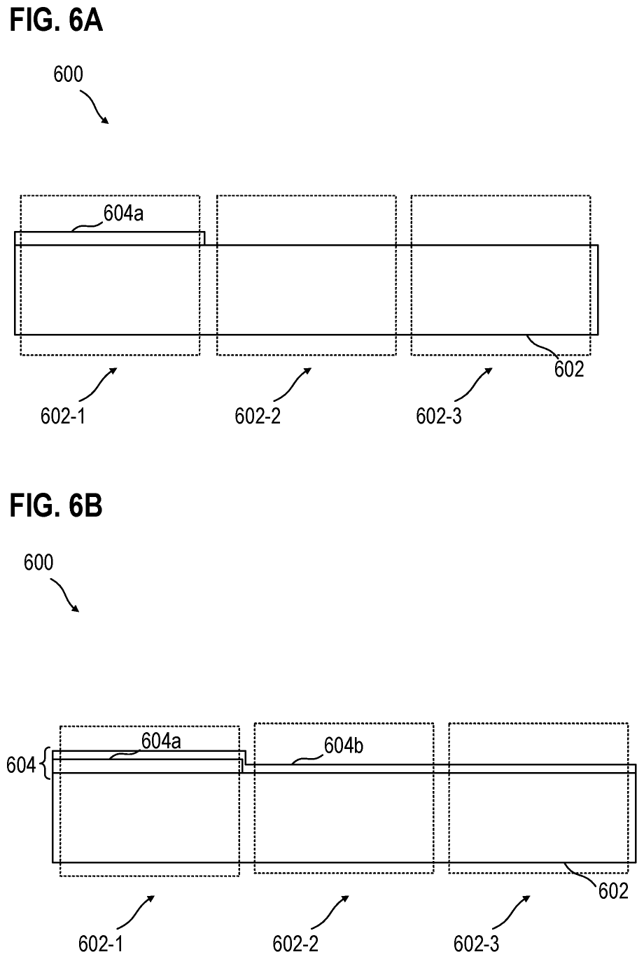

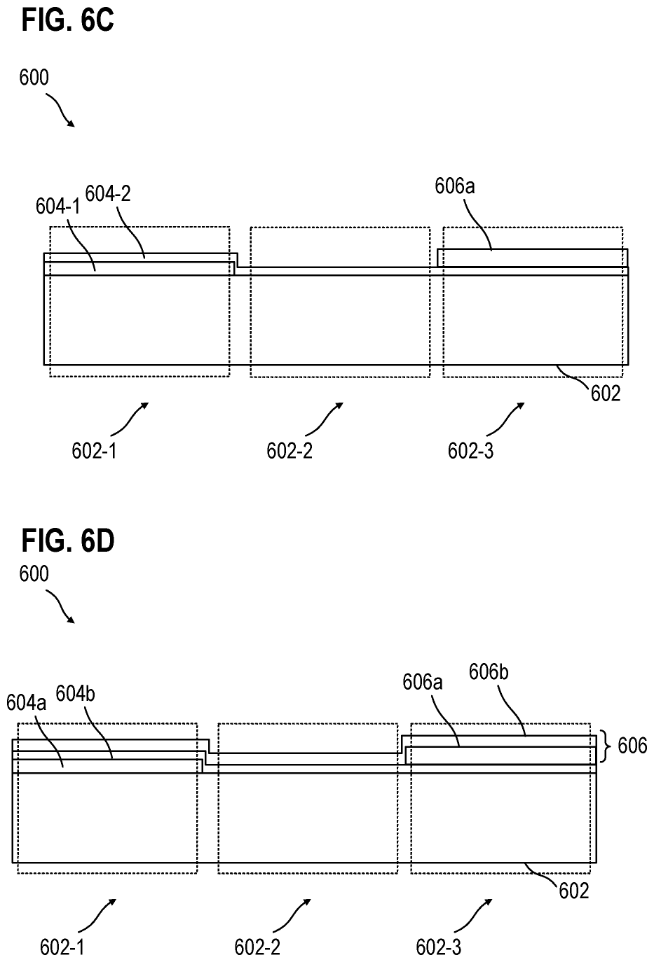

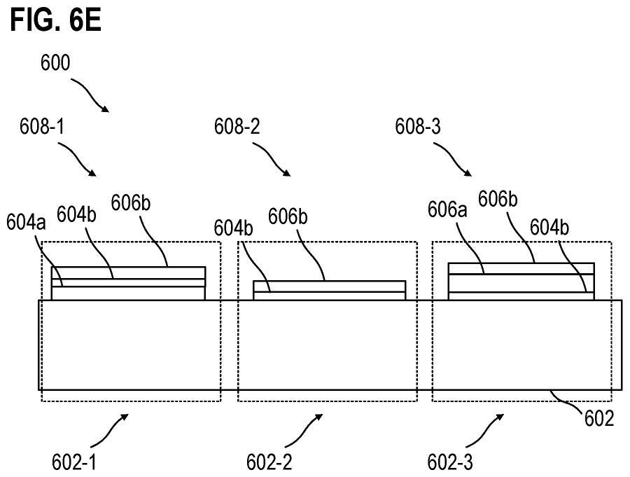

FIG. 6A to FIG. 6E illustrate a method of processing an electronic device 600 by showing a carrier at different processing stages. It is understood that the processing illustrated in FIG. 6A to FIG. 6E serves only as an example of a processing strategy for integrating multiple field-effect transistors of different types in or on a same carrier, and modifications of the method (e.g., additional or alternative processes) may be possible.

A carrier 602 (e.g., a substrate, such as a semiconductor substrate) may be provided. The carrier 602 may have areas assigned to different functionalities. In the exemplary configuration illustrated in FIG. 6A to FIG. 6E the carrier 602 may have a first area 602-1 assigned to input/output operations (e.g., an I/O transistor area 602-1), a second area 602-2 assigned to logic operations (e.g., a logic transistor area 602-2), and a third area 602-3 assigned to memory operations (e.g., a memory transistor area 602-3). Components (e.g., field-effect transistors) of different types may be formed in the different areas (e.g., input/output components in the input/output transistor area 602-1, logic components in the logic transistor area 602-2, and memory components in the memory transistor area 602-3).

In various aspects, providing field-effect transistor of different types (e.g., an I/O transistor in the I/O transistor area 602-1, a logic transistor in the logic transistor area 602-2, and a memory transistor in the memory transistor area 602-3) may include forming gate isolation layers having different thicknesses in the different areas.

In various aspects, a first gate isolation layer 604 (e.g., a buffer layer) may be structured differently in the different areas of the carrier, e.g. depending on the type of field-effect transistor to be formed in the respective area. The first gate isolation layer 604 may include a material having a relatively low dielectric constant (e.g., less than 4 or less than 15), for example a low-k dielectric material. In some aspects, the first gate isolation layer 604 may include silicon dioxide. Illustratively, a first portion of the first gate isolation layer 604 in the I/O transistor area 602-1 may form part of a first (e.g., I/O) field-effect transistor, a second portion of the first gate isolation layer 604 in the logic transistor area 602-2 may form part of a second (e.g., logic) field-effect transistor, and a third portion of the first gate isolation layer 604 in the memory transistor area 602-3 may form part of a third (e.g., memory) field-effect transistor. As described above, the first gate isolation layer 604 may be thicker in an I/O transistor than in a logic transistor or in a memory transistor.

Forming a first gate isolation layer 604 (e.g., a first dielectric layer) on the carrier 602, e.g. on each area of the I/O transistor area 602-1, the logic transistor area 602-2, and the memory transistor area 602-3 may include forming (e.g., depositing or thermally growing) a first layer 604a including (in some aspects, made of) the (e.g., low-k dielectric) material of the first gate isolation layer on the carrier 602, as shown in FIG. 6A. The first layer 604a may be formed in the I/O transistor area 602-1.

As an example, the first layer 604a may be formed on the whole surface of the carrier 602 and then removed from the logic transistor area 602-2 and from the memory transistor area 602-3 (illustratively, from the areas where a thick first gate isolation layer is not required, or where a first gate isolation layer is not required at all). The first layer 604a may be removed, for example, via an etching process (e.g., wet etching or dry etching) in which the first layer 604a in the I/O transistor area 602-1 is covered with a mask (e.g., a hard mask or a soft mask). Following the etching process, the first layer 604a remains in the I/O transistor area 602-1. As another example, the first layer 604a may be selectively formed (e.g., deposited or thermally grown) in the I/O transistor area 602-1 (e.g., by masking the portions of the carrier 602 in the logic transistor area 602-2 and in the memory transistor area 602-3).

Forming a first gate isolation layer 604 may include forming a second layer 604b including (in some aspects, made of) the material of the first gate isolation layer on the carrier 602 (and on the first layer 604-1), as shown in FIG. 6B. Illustratively, the first layer 604a and the second layer 604b may be formed such that the second layer 604b provides the desired thickness of the first gate isolation layer 604 in the logic transistor area 602-2 and in the memory transistor area 602-3, and a combination of the first layer 604a and the second layer 604b provides the desired thickness of the first gate isolation layer 604 in the I/O transistor area 602-1.

Following the deposition process, the first portion of the first gate isolation layer 604 in the I/O transistor area 602-1 may have a thickness in the range from about 1.5 nm to about 7 nm, the second portion of the first gate isolation layer 604 in the logic transistor area 602-2 may have a thickness in the range from about 0.5 nm to about 1.5 nm, and the third portion of the first gate isolation layer 604 in the memory transistor area 602-3 may have a thickness in the range from about 0.5 nm to about 1.5 nm (in some aspects, same as the thickness of the second portion in the logic transistor area 602-2).

In some aspects, the memory transistor area 602-3 may be free from the first gate isolation layer 604. By way of example, the memory area 602-3 may be covered during the formation of the first layer 604a and/or of the second layer 604b in the I/O transistor area 602-1 and in the logic transistor area 602-2. As another example the first layer 604a and the second layer 604b may be removed from the memory transistor area 602-3, e.g. via etching, while using a mask to cover the I/O transistor area 602-1 and the logic transistor area 602-2.

It is understood that forming the first gate isolation layer 604 may also be carried out in different ways, as long as a thicker first gate isolation layer 604 may be provided in the I/O transistor area 602-1.

In various aspects, a second gate isolation layer 606 may be structured differently in the different areas of the carrier, e.g. depending on the type of field-effect transistor formed in the respective area. The second gate isolation layer 606 may include a material having a relatively high dielectric constant, e.g. greater than 4 or greater than 15, e.g. a high-k dielectric material (e.g., hafnium oxide). Illustratively, a first portion of the second gate isolation layer 606 in the I/O transistor area 602-1 may form part of the I/O transistor, a second portion of the second gate isolation layer 606 in the logic transistor area 602-2 may form part of the logic transistor, and a third portion of the second gate isolation layer 606 in the memory transistor area 602-3 may form part of the memory transistor. As described above, the second gate isolation layer 606 may be thicker in a memory transistor than in an I/O transistor or in a logic transistor.

Forming a second gate isolation layer 606 (e.g., a second dielectric layer) on the carrier 602, e.g. on each area of the I/O transistor area 602-1, the logic transistor area 602-2, and the memory transistor area 602-3 may include forming (e.g., depositing or thermally growing) a third layer 606a including (in some aspects, made of) the (e.g., high-k dielectric) material of the second gate isolation layer 606 on the first gate isolation layer 604 (and/or on the carrier 602, e.g. in case the memory transistor area 602-3 is free from the first gate isolation layer 604), as shown in FIG. 6C. The third layer 606a may be formed in the memory transistor area 602-3.

As an example, the third layer 606a may be formed on the whole first gate isolation layer 604 (or the carrier 602) and then removed from the I/O transistor area 602-1 and from the logic transistor area 602-2 and (illustratively, from the areas where a thick second gate isolation layer 606 is not required). The third layer 606a may be removed, for example, via an etching process (e.g., wet etching or dry etching) in which the third layer 606a in the memory transistor area 602-3 is covered with a mask (e.g., a hard mask or a soft mask). Following the etching process, the third layer 606a remains in the memory transistor area 602-3. As another example, the third layer 606a may be selectively formed (e.g., deposited or thermally grown) in the memory transistor area 602-3 (e.g., by masking the portions of the carrier 602 in the I/O transistor area 602-1 and in the logic transistor area 602-2). As another example, the third layer 606a may be selectively formed (e.g., deposited or thermally grown) in the memory transistor area 602-3 (e.g., by masking the portions of the carrier 602 in the I/O transistor area 602-1 and in the logic transistor area 602-2).

Forming a second gate isolation layer 606 may include forming a fourth layer 606b including (in some aspects, made of) the material of the second gate isolation layer 606 on the carrier 602 (and on the first layer 606a), as shown in FIG. 6D. Illustratively, the third layer 606a and the fourth layer 606b may be formed such that the fourth layer 606b provides the desired thickness of the second gate isolation layer 606 in the I/O transistor area 602-1 and in the logic transistor area 602-2, and a combination of the third layer 606a and the fourth layer 606b provides the desired thickness of the second gate isolation layer 606 in the memory transistor area 602-3.

Following the deposition process, the first portion of the second gate isolation layer 606 in the I/O transistor area 602-1 may have a thickness in the range from about 1 nm to about 3 nm, the second portion of the second gate isolation layer 606 in the logic transistor area 602-2 may have a thickness in the range from about 1 nm to about 3 nm (same as the first portion in the input/output area 602-1), and the third portion of the second gate isolation layer 606 in the memory transistor area 602-3 may have a thickness in the range from about 3 nm to about 10 nm.

It is understood that forming the second gate isolation layer 606 may also be carried out in different ways, as long as a thicker second gate isolation layer 606 may be provided in the memory transistor area 602-3.

As shown in FIG. 6E the formed layers in the different areas may be separated from each other (e.g., via etching) to form the respective transistors, e.g. the I/O transistor 608-1 in the I/O transistor area 602-1, the logic transistor 608-2 in the logic transistor area 602-2, and the memory transistor 608-3 in the memory transistor area 602-3.

It is understood that further processing steps (not shown) may be carried out, e.g. to provide corresponding source/drain regions and/or gate electrodes for the transistors formed on or in the carrier.

The word “over”, used herein to describe forming a feature, e.g. a layer “over” a side or surface, may be used to mean that the feature, e.g. the layer, may be formed “directly on”, e.g. in direct contact with, the implied side or surface. The word “over”, used herein to describe forming a feature, e.g. a layer “over” a side or surface, may be used to mean that the feature, e.g. the layer, may be formed “indirectly on” the implied side or surface with one or more additional layers being arranged between the implied side or surface and the formed layer.

The term “lateral” used with regards to a lateral dimension (in other words a lateral extent) of a structure, a portion, a structure element, a layer, etc., provided, for example, over and/or in a carrier (e.g. a layer, a substrate, a wafer, etc.) or “laterally” next to, may be used herein to mean an extent or a positional relationship along a surface of the carrier. That means, in some aspects, that a surface of a carrier (e.g. a surface of a layer, a surface of a substrate, a surface of a wafer, etc.) may serve as reference, commonly referred to as the main processing surface. Further, the term “width” used with regards to a “width” of a structure, a portion, a structure element, a layer, etc., may be used herein to mean the lateral dimension (or in other words the lateral extent) of a structure. Further, the term “height” used with regards to a height of a structure, a portion, a structure element, a layer, etc., may be used herein to mean a dimension (in other words an extent) of a structure in a direction perpendicular to the surface of a carrier (e.g. perpendicular to the main processing surface of a carrier).

The term “connected” may be used herein with respect to nodes, terminals, integrated circuit elements, and the like, to mean electrically connected, which may include a direct connection or an indirect connection, wherein an indirect connection may only include additional structures in the current path that do not influence the substantial functioning of the described circuit or device. The term “electrically conductively connected” that is used herein to describe an electrical connection between one or more terminals, nodes, regions, contacts, etc., may be understood as an electrically conductive connection with, for example, ohmic behavior, e.g. provided by a metal or degenerate semiconductor in absence of p-n junctions in the current path. The term “electrically conductively connected” may be also referred to as “galvanically connected”.

The term region used with regards to a “source region”, “drain region”, “channel region”, and the like, may be used herein to mean a continuous region of a semiconductor portion (e.g., of a semiconductor wafer or a part of a semiconductor wafer, a semiconductor layer, a fin, a semiconductor nanosheet, a semiconductor nanowire, etc.,). In some aspects, the continuous region of a semiconductor portion may be provided by semiconductor material having only one dominant doping type.

The term “thickness” used with regards to a “thickness” of a layer may be used herein to mean the dimension (in other words an extent) of the layer perpendicular to the surface of the support (the material or material structure) on which the layer is formed (e.g., deposited or grown). If a surface of the support is parallel to the surface of the carrier (e.g. parallel to the main processing surface) the “thickness” of the layer formed on the surface of the support may be the same as the height of the layer.

In the present description, the terms “electrically isolating” and “electrically insulating” may be used interchangeably. Similarly, the terms “(electrical) isolation” and “(electrical) insulation” may be used interchangeably.

In the following, various aspects of this disclosure will be illustrated.

Example 1 is a memory cell including: a capacitive memory structure; and a field-effect transistor structure including a gate isolation, wherein the capacitive memory structure and the field-effect transistor structure are coupled with one another to form a capacitive voltage divider, wherein the gate isolation includes at least one gate isolation layer, the at least one gate isolation layer including a material having a dielectric constant greater than 4 (in some aspects, greater than 15), wherein a thickness of the at least one gate isolation layer is in the range from 3 nm to 10 nm.

In Example 2, the memory cell of example 1 may optionally further include that the gate isolation extends from a channel region of the field-effect transistor structure to a gate electrode of the field-effect transistor structure, and that the gate isolation is free of a silicon oxide layer (in some aspects, the gate isolation may be free of silicon oxide).

A structure being free of a layer may be understood, in some aspects, as that layer being present in the structure but the layer having a thickness less than 1 Å or less than 0.5 Å. Illustratively, the gate isolation being free of a silicon oxide layer may be understood as the gate isolation including a silicon oxide layer with thickness less than 1 Å or less than 0.5 Å. In some aspects, a structure being free of a material may be understood as the structure having a content in weight of that material less than 5% (for example less than 1% or less than 0.1%) with respect to the weight of the structure, illustratively a weight percentage (or weight ratio) of that material less than 5%. In some aspects, a structure being free of a material may be understood as the structure having a content in volume of that material less than 5% (for example less than 1% or less than 0.1%) with respect to the volume of the structure, illustratively a volume percentage (or volume ratio) of that material less than 5%. The gate isolation being free of silicon oxide may be understood, in some aspects, as the gate isolation having a content of silicon oxide in weight less than 5% (e.g., less than 1%, or less than 0.1%) with respect to a weight of the gate isolation. The gate isolation being free of silicon oxide may be understood, in some aspects, as the gate isolation having a content of silicon oxide in volume less than 5% (e.g., less than 1%, or less than 0.1%) with respect to a volume of the gate isolation.

In some aspects, the gate isolation may include a first gate isolation layer (e.g., a buffer layer) that is free of silicon oxide. In some aspects, the gate isolation may include a second gate isolation layer that is free of silicon oxide, e.g. a second gate isolation layer consisting of a material with dielectric constant greater than 4 (or greater than 15). In some aspects, the first gate isolation layer (e.g., the buffer layer) may include silicon oxide, and the second gate isolation layer may be free of silicon oxide.

In Example 3, the memory cell of example 1 may optionally further include that the field-effect transistor structure further includes a channel region, and that the gate isolation further includes a buffer layer disposed in direct physical contact with the channel region, wherein a thickness of the buffer layer is less than 1.5 nm.

In Example 4, the memory cell of example 3 may optionally further include that the at least one gate isolation layer is in direct physical contact with the buffer layer and with a gate electrode of the field-effect transistor structure.

In Example 5, the memory cell of example 3 or 4 may optionally further include that the buffer layer includes a material having a dielectric constant less than the dielectric constant of the at least one gate isolation layer (e.g., a difference between the dielectric constant of the material of the buffer layer and the material of the at least one gate isolation layer may be at least three, or at least five).

In Example 6, the memory cell of example 5 may optionally further include that the material of the buffer layer has a dielectric constant less than 15 (in some aspects, a dielectric constant in the range from about 3 to about 15, for example less than 4).

In some aspects a dielectric constant of the material of the at least one gate isolation layer is at least three times greater than a dielectric constant of the material of the buffer layer.

In Example 7, the memory cell of any one of examples 3 to 6 may optionally further include that the material of the buffer layer includes at least one of the following: silicon, silicon oxide, silicon nitride, silicon oxynitride, aluminum, aluminum oxide, aluminum nitride, aluminum oxynitride. In some aspects, the material mentioned in this paragraph may be understood as low-k materials (e.g., in the context of this description).

In Example 8, the memory cell of any one of examples 1 to 7 may optionally further include that the material of the at least one gate isolation layer includes at least one of the following: hafnium, zirconium, lanthanum, strontium, calcium, hafnium oxide, zirconium oxide, silicon doped hafnium oxide, lanthanum oxide, strontium titanate, calcium titanate. In some aspects, the material mentioned in this paragraph may be understood as high-k materials (e.g., in the context of this description).

In Example 9, the memory cell of any one of examples 1 to 8 may optionally further include that the material of the at least one gate isolation layer includes at least one of the following: a transition metal oxide, a perovskite.

In Example 10, the memory cell of any one of examples 1 to 9 may optionally further include that the material of the at least one gate isolation layer has a crystalline structure of at least one of the following types of crystalline structures: a poly-crystalline structure, a mono-crystalline structure (also referred to as single-crystalline structure), an epitaxially formed crystalline structure.

In Example 11, the memory cell of any one of examples 1 to 10 may optionally further include that a first capacitance (e.g., a maximal capacitance) is associated with the field-effect transistor structure, and that a second capacitance (e.g., a minimal capacitance) less than the first capacitance is associated with the capacitive memory structure. In some aspects, a capacitance that is associated with a field-effect transistor structure may not be constant, e.g., may be a function of the voltage that is applied. However, a so-called “dielectric” capacitance may be associated with the field-effect transistor structure that is substantially constant and defines a maximal capacitance of the field-effect transistor structure. The dielectric capacitance of a field-effect transistor structure may be dominant in the case that the channel of the field-effect transistor structure is conductive, e.g., for strong accumulation and for strong inversion, and, otherwise, the capacitance of the field-effect transistor structure may be less than the maximal capacitance. In some aspects, a capacitance that is associated with a capacitive memory structure may not be constant, e.g., may be a function of the voltage that is applied and/or a function of a polarization of the material included in the capacitive memory structure. However, a so-called “dielectric” capacitance may be associated with the capacitive memory structure that is substantially constant and defines a minimal capacitance of the capacitive memory structure. The capacitance of a capacitive memory structure may be greater than the minimal capacitance in the case that the polarization of a remanent-polarizable layer that is included in the capacitive memory structure is polarized and/or switched by an external electrical field.

In Example 12, the memory cell of example 11 may optionally further include that a ratio of the first capacitance to the second capacitance is in the range from about 1 to about 100, for example in the range from about 1 to about 25, for example in the range from about 2 to about 25, for example in the range from about 1 to about 16. In some aspects, a ratio of the first capacitance to the second capacitance may be about 4.

In Example 13, the memory cell of any one of examples 1 to 12 may optionally further include that the gate isolation of the field-effect transistor structure further includes an additional electrically isolating layer.

In some aspects, the additional electrically isolating layer may include an oxide material and/or a nitride material.

In some aspects, the oxide material may be or may include Al₂O₃ or SiO₂.

In Example 14, the memory cell of example 13 may optionally include that the additional electrically isolating layer is disposed between the buffer layer (e.g., the first gate isolation layer) and the at least one gate isolation layer (e.g., the second gate isolation layer). Additionally or alternatively the additional electrically isolating layer may be disposed between the at least one gate isolation layer and a gate electrode of the field-effect transistor structure. Additionally or alternatively, the additional electrically isolating layer may be disposed between the buffer layer and a channel region of the field-effect transistor structure. Additionally or alternatively, the additional electrically isolating layer may be disposed within the at least one gate isolation layer.

In Example 15, the memory cell of any one of examples 1 to 14 may optionally further include that the capacitive memory structure includes a first electrode, a second electrode, and at least one remanent-polarizable layer disposed between the first electrode and the second electrode.

In Example 16, the memory cell of example 15 may optionally further include that the field-effect transistor structure includes a gate electrode that is electrically conductively connected to the first electrode of the capacitive memory structure.

In Example 17, the memory cell of example 15 or 16 may optionally further include that a material of the at least one remanent-polarizable layer includes at least one of the following: hafnium oxide, zirconium oxide, a mixture of hafnium oxide and zirconium oxide.

In Example 18, the memory cell of example 16 may optionally further include that a first footprint is associated with the gate electrode of the field-effect transistor structure, that a second footprint is associated with the first electrode and/or with the second electrode of the capacitive memory structure, and that the first footprint is less than 8 times the second footprint.

In Example 19, the memory cell of example 16 may optionally further include that the first electrode of the capacitive memory structure is in direct physical contact of with the gate electrode of the field-effect transistor structure.

In Example 20, the memory cell of example 16 may optionally further include one or more metallization structures disposed over the field-effect transistor structure, the one or more metallization structures being configured to electrically connect the gate electrode of the field effect transistor structure to the first electrode of the capacitive memory structure.

In Example 21, the memory cell of example 20 may optionally include that at least one metallization structure of the one or more metallization structures is disposed over an active area of the field-effect transistor structure.

Example 22 is a memory cell including: a capacitive memory structure including a first electrode, a second electrode, and at least one remanent-polarizable layer disposed between the first electrode and the second electrode; and a field-effect transistor structure including a gate isolation and a gate electrode, wherein the gate electrode is electrically conductively connected to the first electrode of the capacitive memory structure, wherein the gate isolation includes a buffer layer and a gate isolation layer, the buffer layer including a first material having a first dielectric constant and the gate isolation layer including a second material having a second dielectric constant, wherein the first dielectric constant is less than the first dielectric constant, and wherein a thickness of the buffer layer is less than 1.5 nm and a thickness of the gate isolation layer is in the range from 3 nm to 10 nm.

In some aspects, the thickness of the gate isolation layer is at least two times greater than the thickness of the buffer layer and a sum of the thickness of the buffer layer and the thickness of the gate isolation layer is at least 8 nm.

In Example 23, the memory cell of example 22 may optionally further include that the second dielectric constant is at least three times greater than the first dielectric constant.

In Example 24, the memory cell of example 22 or 23 may optionally further include that the first dielectric constant is less than or equal to 15 (e.g., in the range from 3 to 15, for example a dielectric constant equal to or less than 4), and that the second dielectric constant is greater than 15 (in some aspects, greater than 4).

The memory cell of any one of examples 22 to 24 may include any feature of the memory cell of any one of the examples 1 to 21, where appropriate.

Example 25 is a memory cell including: a capacitive memory structure including a first electrode, a second electrode, and at least one remanent-polarizable layer disposed between the first electrode and the second electrode; and a field-effect transistor structure including a gate isolation and a gate electrode, wherein the gate electrode is electrically conductively connected to the first electrode of the capacitive memory structure, wherein the gate isolation includes a first gate isolation layer and a second gate isolation layer, the first gate isolation layer including a low-k dielectric material and the second gate isolation layer including a high-k dielectric material, wherein a thickness of the first gate isolation layer is in the range from 0.5 nm to 1.5 nm, and wherein a thickness of the second gate isolation layer is at least two times greater than the thickness of the first gate isolation layer.

The memory cell of example 25 may include any feature of the memory cell of any one of the examples 1 to 21, where appropriate.

Example 26 is a memory cell including: a capacitive memory structure including a first electrode, a second electrode, and at least one remanent-polarizable layer disposed between the first electrode and the second electrode; and a field-effect transistor structure including a channel region, a gate electrode, and a gate isolation separating the gate electrode from the channel region, wherein the gate electrode of the field-effect transistor structure is electrically conductively connected to the first electrode of the capacitive memory structure, and wherein the gate isolation of the field-effect transistor structure consists of a high-k dielectric material.

In Example 27, the memory cell of example 26 may optionally include that the gate isolation of the field-effect transistor structure is in direct physical contact with the channel region and with the gate electrode of the field-effect transistor structure.

In Example 28, the memory cell of example 26 or 27 may optionally include that a thickness of the gate isolation of the field-effect transistor structure is greater than 5 nm.

Example 29 is a memory cell including: a capacitive memory structure; and a field-effect transistor structure, the field-effect transistor structure including a gate isolation and a gate electrode, and wherein the capacitive memory structure and the field-effect transistor structure are coupled with one another to form a capacitive voltage divider, wherein the gate isolation of the field-effect transistor structure includes a first gate isolation layer and a second gate isolation layer, the first gate isolation layer including a low-k dielectric material and the second gate isolation layer including a high-k dielectric material, and wherein a thickness of the first gate isolation layer is less than 1.5 nm, and wherein a thickness of the second gate isolation layer is greater than 3 nm.

In Example 30, the memory cell of example 29 may optionally include that the capacitive memory structure includes a first electrode, a second electrode, and at least one remanent-polarizable layer disposed between the first electrode and the second electrode; and that the gate electrode of the field-effect transistor structure is electrically conductively connected to the first electrode of the capacitive memory structure.

The memory cell of example 29 or 30 may include any feature of the memory cell of any one of the examples 1 to 21, where appropriate.

Example 31 is a field-effect transistor structure including a gate isolation and a gate electrode, the gate isolation of the field-effect transistor structure consisting of a high-k dielectric material, wherein a thickness of the gate isolation of the field-effect transistor structure is greater than 5 nm (e.g., at least 10 nm).

Example 32 is a memory cell including: the field-effect transistor structure of example 31; and a capacitive memory structure, wherein the capacitive memory structure and the field-effect transistor structure are coupled with one another to form a capacitive voltage divider.

Example 33 is a method for processing a memory cell, the method including: forming a capacitive memory structure including a first electrode, a second electrode, and at least one remanent-polarizable layer disposed between the first electrode and the second electrode; and forming a field-effect transistor structure including a gate isolation and a gate electrode, wherein the gate electrode is electrically conductively connected to the first electrode of the capacitive memory structure, wherein the gate isolation of the field-effect transistor structure includes a buffer layer and a gate isolation layer, the buffer layer including a first material having a first dielectric constant and the gate isolation layer including a second material having a second dielectric constant, wherein the first dielectric constant is less than the second dielectric constant, and wherein a thickness of the buffer layer is less than 1.5 nm and a thickness of the gate isolation layer is in the range from 3 nm to 10 nm.

In some aspects, a thickness of the gate isolation layer of the gate isolation of the field-effect transistor structure is at least two times greater than a thickness of the buffer layer of the gate isolation of the field-effect transistor structure, and a sum of the thickness of the buffer layer and the thickness of the gate isolation layer is at least 8 nm.

In some aspects, a thickness of the buffer layer of the gate isolation of the field-effect transistor structure is in the range from 0.5 nm to 1.5 nm, and a thickness of the gate isolation layer of the gate isolation of the field-effect transistor structure is at least two times greater than the thickness of the buffer layer.

In Example 34, the method of example 33 may optionally further include that the first dielectric constant is less than or equal to 15 (e.g., in the range from 3 to 15, for example a dielectric constant equal to or less than 4), and that the second dielectric constant is greater than 15 (in some aspects, greater than 4).

The method of example 33 or 34 may include any feature of the memory cell of any one of the examples 1 to 21, where appropriate.

Example 35 is a method for processing a memory cell, the method including: forming a capacitive memory structure; and forming a field-effect transistor structure including a gate isolation and a gate electrode, wherein the capacitive memory structure and the field-effect transistor structure are coupled with one another to form a capacitive voltage divider, wherein the gate isolation of the field-effect transistor structure includes a first gate isolation layer and a second gate isolation layer, the first gate isolation layer including a low-k dielectric material and the second gate isolation layer including a high-k dielectric material, and wherein a thickness of the first gate isolation layer is in the range from 0.5 nm to 1.5 nm, and wherein a thickness of the second gate isolation layer is in the range from 3 nm to 10 nm.

In some aspects, a thickness of the second gate isolation layer of the gate isolation of the field-effect transistor structure is at least two times greater than a thickness of the first gate isolation layer of the gate isolation of the field-effect transistor structure, and a sum of the thickness of the first gate isolation layer and the thickness of the second gate isolation layer is at least 8 nm.

In some aspects, a thickness of the first gate isolation layer of the gate isolation of the field-effect transistor structure is in the range from 0.5 nm to 1.5 nm, and a thickness of the second gate isolation layer of the gate isolation of the field-effect transistor structure is at least two times greater than the thickness of the first gate isolation layer.

Example 36 is a method for processing a memory cell, the method including: forming a capacitive memory structure; and forming a field-effect transistor structure including a gate isolation, wherein the capacitive memory structure and the field-effect transistor structure are coupled with one another to form a capacitive voltage divider, wherein the gate isolation includes at least one gate isolation layer, the at least one gate isolation layer including a material having a dielectric constant greater than 15 (in some aspects, greater than 4), wherein a thickness of the at least one gate isolation layer is in the range from 3 nm to 10 nm.

Example 37 is a method for processing an electronic device, the method including: forming a first gate isolation layer including a material having a dielectric constant less than or equal to 4 (in some aspects, less than or equal to 15) on a carrier, the carrier having an I/O transistor area, a logic transistor area, and a memory transistor area, wherein a first portion of the first gate isolation layer in the I/O transistor area forms part of a first field-effect transistor, a second portion of the first gate isolation layer in the logic transistor area forms part of a second field-effect transistor, and a third portion of the first gate isolation layer in the memory transistor area forms part of a third field-effect transistor, wherein the first portion of the first gate isolation layer in the I/O transistor area has a thickness in the range from about 1.5 nm to about 7 nm, the second portion of the first gate isolation layer in the logic transistor area has a thickness in the range from about 0.5 nm to about 1.5 nm, and the third portion of the first gate isolation layer in the memory area has a thickness in the range from 0.5 nm to 1.5 nm; and forming a second gate isolation layer including a material having a dielectric constant greater than 4 (in some aspects, greater than 15), wherein a first portion of the second gate isolation layer in the I/O transistor area forms part of the first field-effect transistor, a second portion of the second gate isolation layer in the logic transistor area forms part of the second field-effect transistor, and a third portion of the second gate isolation layer in the memory transistor area forms part of the third field-effect transistor, wherein the first portion of the second gate isolation layer in the I/O transistor area has a thickness in the range from about 1 nm to about 3 nm, the second portion of the second gate isolation layer in the logic transistor area has a thickness in the range from about 1 nm to about 3 nm, and the third portion of the second gate isolation layer in the memory transistor area has a thickness in the range from 3 nm to 10 nm.

While the invention has been particularly shown and described with reference to specific aspects, it should be understood by those skilled in the art that various changes in form and detail may be made therein without departing from the spirit and scope of the invention as defined by the appended claims. The scope of the invention is thus indicated by the appended claims and all changes, which come within the meaning and range of equivalency of the claims, are therefore intended to be embraced.

What is claimed is:

1. A memory cell comprising:
a capacitive memory structure; and
a field-effect transistor structure comprising a gate isolation,
wherein the capacitive memory structure and the field-effect transistor structure are coupled with one another to form a capacitive voltage divider,
wherein the gate isolation comprises at least one gate isolation layer, the at least one gate isolation layer comprising a material having a dielectric constant greater than 4, and
wherein a thickness of the at least one gate isolation layer is in the range from 3 nm to 10 nm.

2. The memory cell according to claim 1,
wherein the gate isolation extends from a channel region of the field-effect transistor structure to a gate electrode of the field-effect transistor structure and wherein the gate isolation is free of a silicon oxide layer.

3. The memory cell according to claim 1,
wherein the field-effect transistor structure further comprises a channel region,
wherein the gate isolation further comprises a buffer layer disposed in direct physical contact with the channel region, and
wherein a thickness of the buffer layer is less than 1.5 nm.

4. The memory cell according to claim 3,
wherein the at least one gate isolation layer is in direct physical contact with the buffer layer and with a gate electrode of the field-effect transistor structure.

5. The memory cell according to claim 3,
wherein the buffer layer comprises a material having a dielectric constant less than the dielectric constant of the material of the at least one gate isolation layer.

6. The memory cell according to claim 5,
wherein the material of the buffer layer has a dielectric constant less than 15.

7. The memory cell according to claim 3,
wherein the material of the buffer layer comprises at least one of the following:
silicon,
silicon oxide,
silicon nitride,
silicon oxynitride,
aluminum,
aluminum oxide,
aluminum nitride, and/or
aluminum oxynitride.

8. The memory cell according to claim 1,
wherein the material of the at least one gate isolation layer comprises at least one of the following:
hafnium,
zirconium,
lanthanum,
strontium,
calcium,
hafnium oxide,
zirconium oxide,
silicon doped hafnium oxide,
lanthanum oxide,
strontium titanate, and/or
calcium titanate.

9. The memory cell according to claim 1,
wherein the material of the at least one gate isolation layer comprises at least one of the following:
a transition metal oxide,
a perovskite.

10. The memory cell according to claim 1,
wherein the material of the at least one gate isolation layer has a crystalline structure of at least one of the following types of crystalline structures:
a poly-crystalline structure,
a mono-crystalline structure,
an epitaxially formed crystalline structure.

11. The memory cell according to claim 1,
wherein a first capacitance, C_{FET}, is associated with the field-effect transistor structure,
wherein a second capacitance, C_{CAP}, less than the first capacitance, C_{FET}, is associated with the capacitive memory structure, and
wherein a ratio, C_{FET}/C_{CAP}, of the first capacitance, C_{FET}, to the second capacitance, C_{CAP}, is in the range from about 1 to about 100.

12. The memory cell according to claim 1,
wherein the gate isolation further comprises an additional electrically isolating layer,
wherein the additional electrically isolating layer comprises an oxide material or a nitride material.

13. The memory cell according to claim 1,
wherein the capacitive memory structure comprises a first electrode, a second electrode, and at least one remanent-polarizable layer disposed between the first electrode and the second electrode; and
wherein the field-effect transistor structure comprises a gate electrode that is electrically conductively connected to the first electrode of the capacitive memory structure.

14. The memory cell according to claim 13,
wherein a material of the at least one remanent-polarizable layer comprises at least one of the following:
hafnium oxide,
zirconium oxide,
a mixture of hafnium oxide and zirconium oxide.

15. The memory cell according to claim 13,
wherein a first footprint, F_{GE-FET}, is associated with the gate electrode of the field-effect transistor structure, wherein a second footprint, F_{E-CAP}, is associated with the first electrode and/or with the second electrode of the capacitive memory structure,
and wherein the first footprint, F_{GE-FET}, is less than 8 times the second footprint, F_{E-CAP}.

16. A memory cell comprising:
a capacitive memory structure comprising a first electrode, a second electrode, and at least one remanent-polarizable layer disposed between the first electrode and the second electrode; and
a field-effect transistor structure comprising a gate isolation and a gate electrode, wherein the gate electrode is electrically conductively connected to the first electrode of the capacitive memory structure,
wherein the gate isolation comprises a buffer layer and a gate isolation layer, the buffer layer comprising a first material having a first dielectric constant and the gate isolation layer comprising a second material having a second dielectric constant,
wherein the first dielectric constant is less than the second dielectric constant, and
wherein a thickness of the buffer layer is less than 1.5 nm, and wherein a thickness of the gate isolation layer is in the range from 3 nm to 10 nm.

17. The memory cell according to claim 16,
wherein the second dielectric constant is at least three times greater than the first dielectric constant.

18. The memory cell according to claim 16,
wherein the first dielectric constant is less than or equal to 15, and
wherein the second dielectric constant is greater than 15.

19. Method for processing a memory cell, the method comprising:
forming a capacitive memory structure comprising a first electrode, a second electrode, and at least one remanent-polarizable layer disposed between the first electrode and the second electrode; and
forming a field-effect transistor structure comprising a gate isolation and a gate electrode, wherein the gate electrode is electrically conductively connected to the first electrode of the capacitive memory structure,
wherein the gate isolation comprises a buffer layer and a gate isolation layer, the buffer layer comprising a first material having a first dielectric constant and the gate isolation layer comprising a second material having a second dielectric constant,
wherein the first dielectric constant is less than the second dielectric constant, and
wherein a thickness of the buffer layer is less than 1.5 nm, and wherein a thickness of the gate isolation layer is in the range from 3 nm to 10 nm.

20. The method according to claim 19,
wherein the first dielectric constant is less than or equal to 15, and
wherein the second dielectric constant is greater than 15.
